(19) United States
(12) Patent Application Publication
(10) Pub. No.: US 2025/0219015 A1
(43) Pub. Date: Jul. 3, 2025

(54) METHOD OF BONDING CHIPS AND A SYSTEM FOR PERFORMING THE METHOD

(71) Applicant: CANON KABUSHIKI KAISHA, Tokyo (JP)

(72) Inventors: Nilabh K. Roy, Austin, TX (US); Steven T. Jenkins, Round Rock, TX (US); Byung-Jin Choi, Austin, TX (US)

(21) Appl. No.: 18/399,329

(22) Filed: Dec. 28, 2023

(51) Int. Cl. H01L 23/00; H01L 21/67; H01L 21/68

(52) U.S. Cl. CPC H01L 24/80; H01L 21/67092; H01L 21/67259; H01L 21/681; H01L 24/95; H01L 2224/80121; H01L 2224/8018; H01L 2224/80201; H01L 2224/80379; H01L 2224/80896; H01L 2224/80908; H01L 2224/95; H01L 2924/05442

(57) ABSTRACT

A method for bonding chips includes initially positioning a first bonding head at a first predetermined location relative to an initial position of a substrate chuck, wherein the first bonding head holds a first chip and wherein the substrate chuck supports a bonding surface, initially positioning a second bonding head at a second predetermined location relative to the initial position of the substrate chuck, wherein the second bonding head holds a second chip, alternating between receiving renewed position information of the substrate chuck and repositioning the first bonding head based on the received renewed position information until the first chip contacts the bonding surface, and alternating between receiving renewed position information of the substrate chuck and repositioning the second bonding head based on the received renewed position information until the second chip contacts the bonding surface, and bonding the first chip and the second chip to the bonding surface.

### FIELD OF THE DISCLOSURE

The present disclosure relates to methods of bonding chips including collectively bonding multiple chips.

### RELATED ART

Advanced packaging technologies demand precise and accurate control and placement of chips. For increased productivity/throughput, it is desirable in the art to bond multiple source chips to a bonding surface using multiple bonding heads at the same time. However, even when actuating multiple bonding heads as close to the same time as possible, the chip on one of the bonding heads will invariably contact the bonding surface just prior to the other chips on the other bonding heads. This initial contact by one chip on one bonding head will cause the carriage supporting the bonding surface to tilt about a center of rotation, which in turn causes the substrate chuck and the substrate to tilt. The tilting of the carriage about the center of rotation induces increased or instable alignment for the chips on the remaining bonding heads. Additionally, there are often factors outside of the operators control that will cause disturbances to the position of the substrate throughout the bonding process in all possible dimensions (X, Y, Z, tilt, tip, rotation). These disturbances may also result in misalignment.

FIG. 24 shows a schematic side view of the bonding portion 1 of a bonding system in which the tilting about the center of rotation of a carriage occurs. The bonding portion 1 includes bonding heads 2 coupled with a bridge 3. Below the bonding heads 2 is a carriage 4 holding a substrate chuck 5 with a substrate 6. The carriage 4 rides on a base 8 via a bearing 7. FIG. 24 shows a moment when the bonding heads 2 have attempted to bond two chips 9 to a bonding surface 10 on the substrate 6. However, as noted above, even if it is attempted to bond the two chips 9 to the bonding surface 10 at the same time, invariably, one of the chips will contact the bonding surface 10 first. As shown in FIG. 24, when this happens, the carriage 4, including all of the structure it carries, will rotate in direction 11 about the center of rotation CR. This rotation causes an offset angle 12 that will negatively impact the alignment of the second chip that comes into contact with the bonding surface 10 after the first chip contacts the bonding surface 10. The rotation causes alignment errors for the bonding of the next chip. Such an additional error is difficult to compensate for as the tilt amount will vary depending on the bonding locations. In the system of FIG. 24, a tilt of the carriage 4 of greater than 0.2 μradians caused by the bonding process will result in an alignment error on the order of, for example, greater than 10 nm. The relationship between the alignment error and tilt may be a function of a distance in the bonding direction (Z-axis) between the center of rotation CR of the carriage 4. While not illustrated in FIG. 3, as noted above, other unpreventable disturbances can occur at any moment during the bonding surface that cause the substrate to move from the initial position in all of the possible dimensions (X, Y, Z, tip, tilt, rotation).

Thus, there is a need in the art for a method and system for bonding multiple source chips to a bonding surface while eliminating or minimizing alignment error due to tilt about a center of rotation of the carriage and/or other disturbances.

### SUMMARY

A method for bonding chips includes initially positioning a first bonding head at a first predetermined location relative to an initial position of a substrate chuck, wherein the first bonding head holds a first chip and wherein the substrate chuck supports a bonding surface, initially positioning a second bonding head at a second predetermined location relative to the initial position of the substrate chuck, wherein the second bonding head holds a second chip, alternating between receiving renewed position information of the substrate chuck and repositioning the first bonding head based on the received renewed position information until the first chip contacts the bonding surface, and alternating between receiving renewed position information of the substrate chuck and repositioning the second bonding head based on the received renewed position information until the second chip contacts the bonding surface, and bonding the first chip and the second chip to the bonding surface.

A system for bonding chips includes a first bonding head configured to hold a first chip, a second bonding head configured to hold a second chip, a substrate chuck supporting a bonding surface, one or more processors, and one or more memories storing instructions, when executed by the one or more processors, causing the system to: initially position the first bonding head at a first predetermined location relative to an initial position of a substrate chuck, initially position a second bonding head at a second predetermined location relative to the initial position of the substrate chuck, alternate between receiving renewed position information of the substrate chuck and repositioning the first bonding head based on the received renewed position information until the first chip contacts the bonding surface, alternate between receiving renewed position information of the substrate chuck and repositioning the second bonding head based on the received renewed position information until the second chip contacts the bonding surface, and bond the first chip and the second chip to the bonding surface.

A method of manufacturing a plurality of articles includes initially positioning a first bonding head at a first predetermined location relative to an initial position of a substrate chuck, wherein the first bonding head holds a first chip and wherein the substrate chuck supports a substrate, initially positioning a second bonding head at a second predetermined location relative to the initial position of the substrate chuck, wherein the second bonding head holds a second chip, alternating between receiving renewed position information of the substrate chuck and repositioning the first bonding head based on the received renewed position information until the first chip contacts the substrate, alternating between receiving renewed position information of the substrate chuck and repositioning the second bonding head based on the received renewed position information until the second chip contacts the substrate, bonding the first chip and the second chip to the substrate, singulating the substrate to produce the plurality of articles.

### BRIEF DESCRIPTION OF THE DRAWINGS

Implementations are illustrated by way of example and are not limited in the accompanying figures.

FIG. 1 shows a schematic side view of a bonding system, in accordance with an example embodiment.

FIG. 2 shows a schematic enlarged view of a portion of FIG. 1, in accordance with an example embodiment.

FIG. 3 shows a flowchart of a method for bonding chips using the bonding system of FIG. 1, in accordance with an example embodiment.

FIG. 4 shows a timing chart indicating the changes in state of four bonding heads during a bonding process, in accordance with an example embodiment.

FIG. 5A is a schematic top view of an example embodiment where four bonding heads are positioned relative to the surface of a substrate at the time t1 of FIG. 4, in accordance with an example embodiment.

FIG. 5B is a schematic side view of the bonding heads and substrate of FIG. 5A, in which the Y and Z dimensions are visible, at the same time t1, in accordance with an example embodiment.

FIG. 5C is a schematic side view of the opposite side compared to FIG. 5B and also shows the bonding head and substrate such that the Y and Z dimensions are visible, in accordance with an example embodiment.

FIG. 5D is a schematic side view of the bonding heads and substrate in which the X and Z dimensions are visible, at the same time t1, in accordance with an example embodiment.

FIG. 5E is a schematic side view of the opposite side compared to FIG. 5D and also shows the bonding head and substrate such that the X and Z dimensions are visible, in accordance with an example embodiment.

FIG. 6A is a schematic top view of the bonding heads and substrate corresponding to the time t2 of FIG. 4, in accordance with an example embodiment.

FIG. 6B is a schematic side view of the bonding heads and substrate in which the Y and Z dimensions are visible, at the same time t2, in accordance with an example embodiment.

FIG. 6C is a schematic side view of the opposite side compared to FIG. 6B and also shows the bonding head and substrate such that the Y and Z dimensions are visible, in accordance with an example embodiment.

FIG. 6D is a schematic side view of the bonding heads and substrate in which the X and Z dimensions are visible, at the same time t2, in accordance with an example embodiment.

FIG. 6E is a schematic side view of the opposite side compared to FIG. 6D and also shows the bonding head and substrate such that the X and Z dimensions are visible, in accordance with an example embodiment.

FIG. 7A is a schematic top view of the bonding heads and substrate corresponding to the time t3 of FIG. 4, in accordance with an example embodiment.

FIG. 7B is a schematic side view of the bonding heads and substrate in which the Y and Z dimensions are visible, at the same time t3, in accordance with an example embodiment.

FIG. 7C is a schematic side view of the opposite side compared to FIG. 7B and also shows the bonding head and substrate such that the Y and Z dimensions are visible, in accordance with an example embodiment.

FIG. 7D is a schematic side view of the bonding heads and substrate in which the X and Z dimensions are visible, at the same time t3, in accordance with an example embodiment.

FIG. 7E is a schematic side view of the opposite side compared to FIG. 7D and also shows the bonding head and substrate such that the X and Z dimensions are visible, in accordance with an example embodiment.

FIG. 8A is a schematic top view of the bonding heads and substrate corresponding to the time t4 of FIG. 4, in accordance with an example embodiment.

FIG. 8B is a schematic side view of the bonding heads and substrate in which the Y and Z dimensions are visible, at the same time t4, in accordance with an example embodiment.

FIG. 8C is a schematic side view of the opposite side compared to FIG. 8B and also shows the bonding head and substrate such that the Y and Z dimensions are visible, in accordance with an example embodiment.

FIG. 8D is a schematic side view of the bonding heads and substrate in which the X and Z dimensions are visible, at the same time t4, in accordance with an example embodiment.

FIG. 8E is a schematic side view of the opposite side compared to FIG. 8D and also shows the bonding head and substrate such that the X and Z dimensions are visible, in accordance with an example embodiment.

FIG. 9A is a schematic top view of the bonding heads and substrate corresponding to the time t5 of FIG. 4, in accordance with an example embodiment.

FIG. 9B is a schematic side view of the bonding heads and substrate in which the Y and Z dimensions are visible, at the same time t5, in accordance with an example embodiment.

FIG. 9C is a schematic side view of the opposite side compared to FIG. 9B and also shows the bonding head and substrate such that the Y and Z dimensions are visible, in accordance with an example embodiment.

FIG. 9D is a schematic side view of the bonding heads and substrate in which the X and Z dimensions are visible, at the same time t5, in accordance with an example embodiment.

FIG. 9E is a schematic side view of the opposite side compared to FIG. 9D and also shows the bonding head and substrate such that the X and Z dimensions are visible, in accordance with an example embodiment.

FIG. 9F is a schematic side view of the bonding heads and substrate in which the Y and Z dimensions are visible, at the same time t5 which shows the product substrate tilting (θy) in a first direction, in accordance with an example embodiment.

FIG. 9G is a schematic side view of the opposite side compared to FIG. 9F showing the tilting of the product substrate, in accordance with an example embodiment.

FIG. 10A is a schematic top view of the bonding heads and substrate corresponding to the time t6 of FIG. 4.

FIG. 10B is a schematic side view of the bonding heads and substrate in which the Y and Z dimensions are visible, at the same time t6, in accordance with an example embodiment.

FIG. 10C is a schematic side view of the opposite side compared to FIG. 10B and also shows the bonding head and substrate such that the Y and Z dimensions are visible, in accordance with an example embodiment.

FIG. 10D is a schematic side view of the bonding heads and substrate in which the X and Z dimensions are visible, at the same time t6, in accordance with an example embodiment.

FIG. 10E is a schematic side view of the opposite side compared to FIG. 10D and also shows the bonding head and substrate such that the X and Z dimensions are visible, in accordance with an example embodiment.

FIG. 10F is a schematic side view of the bonding heads and substrate in which the Y and Z dimensions are visible, at the same time t6 which shows the product substrate still tilted in the first direction, in accordance with an example embodiment.

FIG. 10G is a schematic side view of the opposite side compared to FIG. 10F showing the bonding head stages of the bonding heads and tilting the chip chucks, in accordance with an example embodiment.

FIG. 11A is a schematic top view of the bonding heads and substrate corresponding to the time t7 of FIG. 4, in accordance with an example embodiment.

FIG. 11B is a schematic side view of the bonding heads and substrate in which the Y and Z dimensions are visible, at the same time t7, in accordance with an example embodiment.

FIG. 11C is a schematic side view of the opposite side compared to FIG. 11B and also shows the bonding head and substrate such that the Y and Z dimensions are visible, in accordance with an example embodiment.

FIG. 11D is a schematic side view of the bonding heads and substrate in which the X and Z dimensions are visible, at the same time t7, in accordance with an example embodiment.

FIG. 11E is a schematic side view of the opposite side compared to FIG. 11D and also shows the bonding head and substrate such that the X and Z dimensions are visible, in accordance with an example embodiment.

FIGS. 11F and 11G are schematic side views of the bonding heads and substrate in which the Y and Z dimensions are visible, at the same time t7 which shows the product substrate tilted (θy) in a first direction, while a bonding head contacts the product substrate.

FIG. 12A is a schematic top view of the bonding heads and substrate corresponding to the time t8 of FIG. 4, in accordance with an example embodiment.

FIG. 12B is a schematic side view of the bonding heads and substrate in which the Y and Z dimensions are visible, at the same time t8, in accordance with an example embodiment.

FIG. 12C is a schematic side view of the opposite side compared to FIG. 12B and also shows the bonding head and substrate such that the Y and Z dimensions are visible, in accordance with an example embodiment, in accordance with an example embodiment.

FIG. 12D is a schematic side view of the bonding heads and substrate in which the X and Z dimensions are visible, at the same time t8, in accordance with an example embodiment.

FIG. 12E is a schematic side view of the opposite side compared to FIG. 12D and also shows the bonding head and substrate such that the X and Z dimensions are visible, in accordance with an example embodiment, in accordance with an example embodiment.

FIGS. 12F and 12G are schematic side views of the bonding heads and substrate in which the Y and Z dimensions are visible, at the same time t8 which shows the product substrate tilted (θy) in a second direction, after a bonding contacts the product substrate inducing a tilt θy, in accordance with an example embodiment.

FIG. 13A is a schematic top view of the bonding heads and substrate corresponding to the time t9 of FIG. 4, in accordance with an example embodiment, in accordance with an example embodiment.

FIG. 13B is a schematic side view of the bonding heads and substrate in which the Y and Z dimensions are visible, at the same time t9, in accordance with an example embodiment.

FIG. 13C is a schematic side view of the opposite side compared to FIG. 13B and also shows the bonding head and substrate such that the Y and Z dimensions are visible, in accordance with an example embodiment.

FIG. 13D is a schematic side view of the bonding heads and substrate in which the X and Z dimensions are visible, at the same time t9, in accordance with an example embodiment.

FIG. 13E is a schematic side view of the opposite side compared to FIG. 13D and also shows the bonding head and substrate such that the X and Z dimensions are visible, in accordance with an example embodiment.

FIGS. 13F and 13G are schematic side views of the bonding heads and substrate in which the Y and Z dimensions are visible, at the same time t9 which shows the product substrate tilted (θy) in a second direction, in accordance with an example embodiment.

FIG. 14A is a schematic top view of the bonding heads and substrate corresponding to the time t10 of FIG. 4, in accordance with an example embodiment.

FIG. 14B is a schematic side view of the bonding heads and substrate in which the Y and Z dimensions are visible, at the same time t10, in accordance with an example embodiment.

FIG. 14C is a schematic side view of the opposite side compared to FIG. 14B and also shows the bonding head and substrate such that the Y and Z dimensions are visible, in accordance with an example embodiment.

FIG. 14D is a schematic side view of the bonding heads and substrate in which the X and Z dimensions are visible, at the same time t10, in accordance with an example embodiment.

FIG. 14E is a schematic side view of the opposite side compared to FIG. 14D and also shows the bonding head and substrate such that the X and Z dimensions are visible, in accordance with an example embodiment.

FIGS. 14F and 14G are schematic side views of the bonding heads and substrate in which the Y and Z dimensions are visible, at the same time t10 which shows the product substrate tilted (θy) in a second direction, in accordance with an example embodiment.

FIG. 15A is a schematic top view of the bonding heads and substrate corresponding to the time t11 of FIG. 4, in accordance with an example embodiment.

FIG. 15B is a schematic side view of the bonding heads and substrate in which the Y and Z dimensions are visible, at the same time t11, in accordance with an example embodiment.

FIG. 15C is a schematic side view of the opposite side compared to FIG. 15B and also shows the bonding head and substrate such that the Y and Z dimensions are visible, in accordance with an example embodiment.

FIG. 15D is a schematic side view of the bonding heads and substrate in which the X and Z dimensions are visible, at the same time t11, in accordance with an example embodiment.

FIG. 15E is a schematic side view of the opposite side compared to FIG. 15D and also shows the bonding head and substrate such that the X and Z dimensions are visible, in accordance with an example embodiment.

FIGS. 15F and 15G are schematic side views of the bonding heads and substrate in which the Y and Z dimensions are visible, at the same time t11 which shows the product substrate tilted (θy) in a first direction in response a chip contacting the product substrate, in accordance with an example embodiment.

FIG. 16A is a schematic top view of the bonding heads and substrate corresponding to the time t12 of FIG. 4, in accordance with an example embodiment.

FIG. 16B is a schematic side view of the bonding heads and substrate in which the Y and Z dimensions are visible, at the same time t12, in accordance with an example embodiment.

FIG. 16C is a schematic side view of the opposite side compared to FIG. 16B and also shows the bonding head and substrate such that the Y and Z dimensions are visible, in accordance with an example embodiment.

FIG. 16D is a schematic side view of the bonding heads and substrate in which the X and Z dimensions are visible, at the same time t12, in accordance with an example embodiment.

FIG. 16E is a schematic side view of the opposite side compared to FIG. 16D and also shows the bonding head and substrate such that the X and Z dimensions are visible, in accordance with an example embodiment.

FIGS. 16F and 16G are schematic side views of the bonding heads and substrate in which the Y and Z dimensions are visible, at the same time t12 which shows the product substrate tilted (θy) in a first direction and the bonding head stage of the of the a bonding head moving the chip chuck to align with the tilt of the product substrate, in accordance with an example embodiment.

FIG. 17A is a schematic top view of the bonding heads and substrate corresponding to the time t13 of FIG. 4, in accordance with an example embodiment.

FIG. 17B is a schematic side view of the bonding heads and substrate in which the Y and Z dimensions are visible, at the same time t13, in accordance with an example embodiment.

FIG. 17C is a schematic side view of the opposite side compared to FIG. 17B and also shows the bonding head and substrate such that the Y and Z dimensions are visible, in accordance with an example embodiment.

FIG. 17D is a schematic side view of the bonding heads and substrate in which the X and Z dimensions are visible, at the same time t13, in accordance with an example embodiment.

FIG. 17E is a schematic side view of the opposite side compared to FIG. 14D and also shows the bonding head and substrate such that the X and Z dimensions are visible, in accordance with an example embodiment.

FIGS. 17F and 17G are schematic side views of the bonding heads and substrate in which the Y and Z dimensions are visible, at the same time t13 which shows the product substrate tilted (θy) in a first direction and a chip brought into contact with the product substrate, in accordance with an example embodiment.

FIG. 18 shows a timing chart of the X dimension position of the four bonding heads and the substrate of the example embodiment.

FIG. 19 shows a timing chart of the Z dimension position of the four bonding heads and the substrate of the example embodiment.

FIG. 20 shows a timing chart of the total Z direction force imparted by of the four bonding heads of the example embodiment.

FIG. 21 shows a timing chart of the residual force of the four bonding heads of the example embodiment.

FIG. 22 shows the same timing chart of FIG. 4 alongside FIGS. 18-21.

FIG. 23 shows a flowchart and information flow diagram of a controller implementing the method for bonding chips using the bonding system of FIG. 1, in accordance with an example embodiment.

FIG. 24 show a schematic side view of a related art bonding system in which a carriage is being tilted during a bonding process.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the invention.

### DETAILED DESCRIPTION

The following description in combination with the figures is provided to assist in understanding the teachings disclosed herein. The following discussion will focus on specific implementations and implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

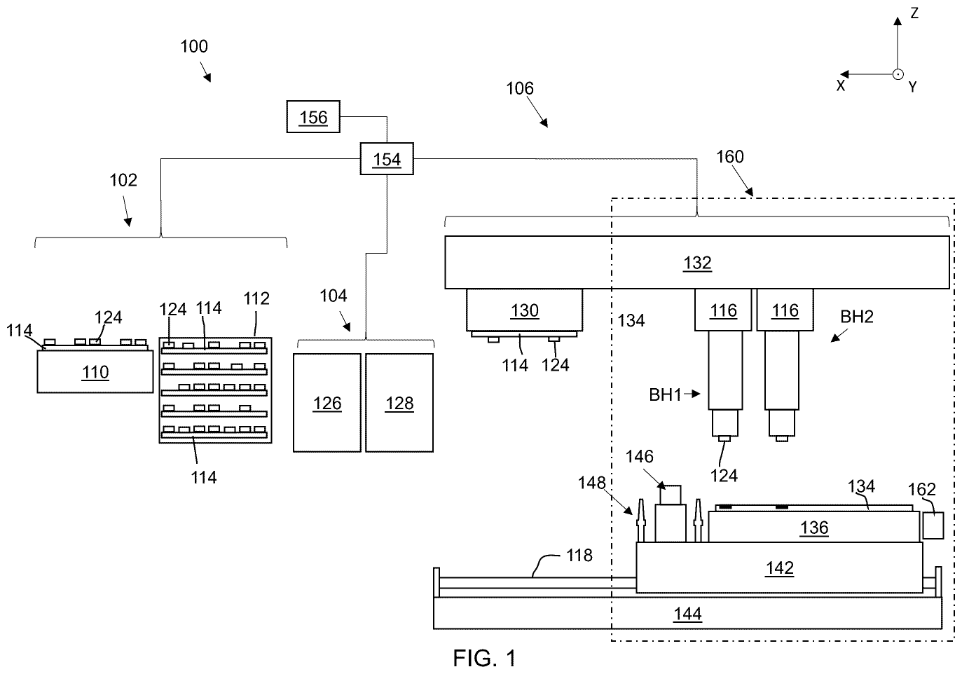

FIG. 1 shows a schematic side view of a bonding system 100 in accordance with an example embodiment. As shown in FIG. 1, the bonding system 100 includes a chip source section 102, a chip transfer and activation section 104, and a chip bonding section 106. The chip source section 102 is the portion of the overall bonding system 100 that contains the source chips that will be used in the bonding process. The chip transfer and activation section 104 is the portion of the overall bonding system 100 that transfers the chips from the chip source section 102 to the chip bonding section 106. In another configuration, the chip source section can be a separate apparatus. Similarly, the chip activation section can be a separate apparatus. The chip transfer and activation section 104 also activates the source chips so the source chips are ready for bonding. In an alternative embodiment, the activation section 104 activates the plurality of chips 124 prior to the chips being placed in the chip source section 102. The chip bonding section 106 receives chips that have been activated and then performs the bonding.

The chip source section 102 includes one or more sources for chips. For example, as shown in FIG. 1, the chip source section may include a substrate 114 held by a source chuck 110 with chips 124 thereon and/or may include a front opening unified/universal pod 112 (known in the art as a “FOUP”). The FOUP may include a plurality of the substrates 114 and chips 124. Other chip sources known in the art may be used in the chip source section 102 such as trays, adhesive tape in a frame, adhesive layer on a stiff substrate, etc. As used herein, chip means an integrated circuit, also referred to as a microchip, a computer chip, etc. A chip may be defined as a small block of semiconducting material on which a given functional circuit is fabricated. In the context of a wafer/substrate that has been divided into individual chips, the chip is known is a die. The chip will typically carry a set of integrated electronic components and circuits formed on it by patterning, coating, etching, doping, plating, singulating, etc. The chip will typically have electrical functions such as: memory, logic, field programmable gate arrays (FPGA), accelerator circuits, application-specific integrated circuits (ASICs), security co-processors, graphics processing units (GPUs), machine learning circuits, specialized processors, controllers, devices, electrical circuits, arrays of passive components, etc. The chip may also be a micro-electromechanical systems (MEMS) device, an optical device, an electrical-optical device, etc.

The chip transfer and activation section 104 includes a transfer robot 126 that is able to lift and carry a substrate 114 to a second substrate chuck 130 in the bonding section 106. As understood in the art, the transfer robot 126 generally includes a hand and a robot arm that provides the degrees of motion to lift, carry, and place a substrate from one location to another, such as from one substrate chuck to another or from a substrate storage location to a substrate chuck. The transfer robot 126 may be any suitable device known in the art, for example robots such as the wafer handling robot RR756L15 provided by Rorze Corporation of Fukuyama-shi, Hiroshima-ken, Japan. The chip transfer and activation device 104 further includes an activation device 128. The activation device 128 is a device that prepares the chips being transferred for hybrid bonding. Hybrid bonding is a chip bonding technique in which electrically insulating (silicon dioxide) chip surfaces with recessed metallic (e.g. copper) pads are brought into contact with each other. The metallic pads are aligned with each other, while the electrically insulating surfaces are bonded to each other via direct contact. Heat is then applied to the bonded structure which causes the metallic pads to expand more relative to the electrically insulating material and contact each other, thus forming electrical connections between the chips. In an example embodiment, the activation device 128 may include a fluid source that applies for example deionized water and possibly a plasma source that activates the surface of the chips prior to them being carried by the transfer robot 126. Due to the materials of the chips (i.e., dielectric), when the activated chip is brought into contact with another chip a fusion bond will occur between the dielectric surfaces of the two chips.

The bonding section 106 includes the second substrate chuck 130 for receiving the substrate 114 that has been carried by the transfer robot 126 and has chips that have been activated by the activation device 128. The second substrate chuck 130 is also referred herein as an intermediate substrate chuck. The bonding section 106 may include a bridge 132 to which the intermediate substrate chuck 130 is attached. The bonding section 106 also includes a plurality of bonding heads 134 attached to the bridge 132.

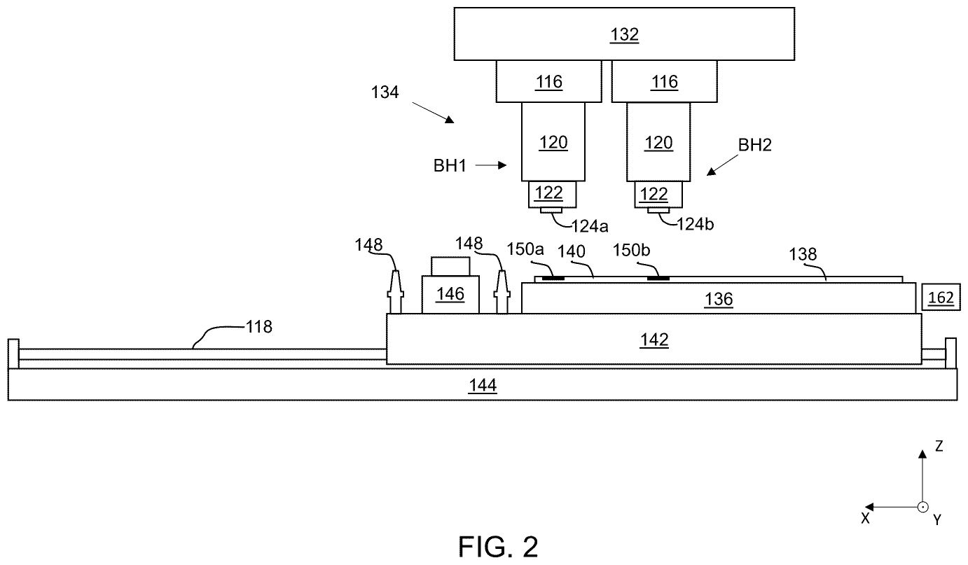

FIG. 2 shows a schematic closeup view of a portion 160 of the bonding section 106. As seen in FIG. 2, the bonding heads 134 may include a bonding head base 116, a bonding head stage 120, bonding head sensors (not shown) and a chip chuck 122. The bonding head sensors can include interferometric, spectral interference, linear encoders, rotary encoders, capacitive sensors, potentiometric sensors, inductive sensors etc. that are used to provide information of the relative position of the chip chuck. A processor may use information from the bonding head sensors to control the position of chip chuck with the bonding head stage. The chip chuck holds the back surface of the chips 124 along the perimeter of the chip. In the illustrated embodiment shown in FIG. 2, a first bonding head BH1 is holding a first chip 124a and a second bonding head BH2 is holding a second chip 124b (as well as a third bonding BH3 holding a third chip 124c and a fourth bonding head BH4 holding a fourth chip 124d, which are illustrated in subsequent figures). As discussed below, additional bonding heads and additional chips may be present. The bonding head stage 120 may include a bonding head base 116 and include one or more actuators that move the chip chuck in at least the Z direction towards a product substrate chuck 136 relative to the bonding head base 116. The bonding head stage 120 may include one or more actuators that move the chip chuck 122 in up to six directions ((X dimension, Y dimension, Z dimension, tip (Ox, rotation about X axis), tilt (θy, rotation about Y axis), and Oz, rotation about the Z axis). The bonding stage is a mechanical motion system that can manipulate the chip in the desired motion directions. It may comprise of the bearing mechanisms and actuators necessary to facilitate the motion in the desired directions. The bonding stage 120 may be a series of stages that are stacked on top of each other moving the chip chuck 122. An alternative design of the system uses a single stage with parallel kinematics to enable multi DoF (degree of freedom) motion. Each of the stages may move the chip chuck along a single axis of the six possible axes. One or more of the stages may move the chip along more than one of the six possible axes. The bonding stage 120 may be a multiple axes positioner with multiple actuators and parallel kinematics for moving the chip chuck 122 along up to six axes. An example of a multiple axes positioner is a hexapod stage that includes multiple actuators each actuators attached to two swivel joints. Thus, in total, the chip is able to move in six dimensions: X, Y, Z, tip, tilt, rotation. The actuators may be voice coil motors, piezoelectric motors, linear motors, nut and screw motors, piezo-actuated stages, brushless DC motor stages, DC motor stages stepper motors, which are configured to move the chip chuck 122 to and from the product substrate chuck 136 and to apply a controlled force to the chip 124 when it is in contact with the bonding surface 140. The chip chuck 122 may hold the chip 124 to the chucking surface using: vacuum; electrostatic forces; electromagnetic forces; mechanical gripping forces; or any other method of releasably holding the chip to the chucking surface of the bonding head 134. The bonding section 106 further includes a product substrate chuck 136 holding a product substrate 138. The product substrate 138 has a bonding surface 140. The bonding surface 140 in the illustrated example embodiment is the upper surface of the product substrate 138. In another example embodiment, the bonding surface may be a surface of a chip already on the product substrate 138. That is, the bonding described herein may be used to bond source chips onto the surface of a product substrate and/or may be used to bond source chips to the surface of a product chip on the product substrate.

The bonding system 106 may further include sensors to determine the position of the product substrate 138. More particularly, the sensors detect the X dimension position, Y dimension position, tip position, tilt position, and rotation position of the product substrate chuck 136 relative to a starting/initial position of the product substrate chuck 136. FIG. 2 shows a first sensor to measure X dimension position, a second sensor (not shown) to measure Y dimension position, a third sensor (not shown) to measure Z dimension position, and may include additional sensors. The bonding system 106 includes a number of sensors arranged around the substrate chuck 136 to obtain the substrate's position, posture or both. These sensor measure one or more of the X dimension position, the Y dimension position, the tip position, the tilt position, and the rotation position. These sensors can be either optical-interferometric, spectral interference, linear encoders, rotary encoders, capacitive sensors, potentiometric sensors, inductive sensors etc. One or more of the positions may be calculated based on the measurement of multiple sensors. Because the product substrate chuck 136 holds the substrate, the position information of the substrate chuck also informs the relative position of the substrate 138. Thus, the location of the substrate chuck and the location of the substrate are used interchangeably herein. The starting/initial position of the substrate chuck 136 and substrate 138 is the position shown in FIG. 2 prior to performing the bonding method discussed below.

As shown in FIGS. 1 and 2, the bonding system 106 further includes a carriage 142 that supports the substrate chuck 136 and the one or more transfer heads 148 and the one or more alignment devices (not shown). The carriage 142 may rest on bearings 118 and may be part of a substrate chuck positioning system. The substrate chuck positioning system may include one or more motion stages for providing up to 6 degree of freedom motion of the substrate chuck relative to the parallel set of bonding heads.

As noted above, the bonding section 106 may further include a plurality of alignment devices 146 and a plurality of transfer heads 148, all of which are also carried by the carriage 142. As shown in FIG. 1, the bearings 118 of the carriage 142 may support the alignment devices 146 and the transfer heads 148. Each of the plurality of transfer heads 148, may include any one of a variety of methods of holding the chips including but not limited to: a Bernoulli chuck; a suction nozzle; an electrostatic chuck; an edge gripping chuck; a latching mechanism; or any method of releasably holding a chip. Each of the plurality of transfer heads 148, may include an actuator for moving in at least the Z direction towards and away from the bridge 132. The plurality of alignment devices 146 are used to examine the alignment of chips on the plurality of bonding heads 134 after the chips have been transferred to the plurality of bonding heads 134. Each alignment device may be a microscope, a camera, an interferometer, or any sort of measuring device that is capable of measuring the position of each chip on a sub-mm, micron, or nanometer scale. The information provided by the plurality of alignment devices 146 will allow the operator to know whether each chip is at a target position within an acceptable amount of error. The plurality of alignment devices 146 may be any suitable device known in the art, for example a 20× microscope with 5 megapixel camera such as a CI-5MGMCL from Canon Inc., of Tokyo Japan. The plurality of transfer heads 148 are used to transfer the chips from the substrate 114 that is held by the intermediate substrate chuck 130 to the plurality of bonding heads 134.

The number of bonding heads of the plurality of bonding heads is at least two but can be as many as 300. The number of bonding heads may be 2 to 300, 5 to 100, or 8 to 16, for example. The arrangement of the plurality of bonding heads may be in the form of columns and rows such as one by two, two by one, two by two, one by three, three by one, two by three, three by two, three by three, four by one, one by four, four by two, two by four, three by four, four by three, four by four, etc. In the illustrated example embodiment, the bonding heads are two by two, for a total of four bonding heads. The number and arrangement of transfer heads of the plurality of transfer heads may be the same as the number and arrangement of the bonding heads. Or the number and arrangement of transfer heads of the plurality of transfer heads can be larger than those of the bonding heads.

The bonding section 106 may further include a microscope (not shown) on the carriage 142 and a microscope (not shown) on the bridge 132. The microscope on the carriage 142 is moveable along with the plurality of transfer heads 148, the product substrate chuck 136, and the plurality of alignment devices 146. The microscope on the carriage is aimed upwardly in a direction toward the intermediate substrate chuck 130. The microscope on the carriage functions to measure positions of the plurality of chips on the substrate 114. The microscope on the bridge faces downward in a direction toward the product substrate chuck 136. The microscope on the bridge functions to measure positions of the chips on the product substrate 138. Each of the microscopes may be suitable device known in the art, for example a 20× microscope with a 5 megapixel camera such as a CI-5MGMCL from Canon Inc., of Tokyo Japan.

The bonding system 100 may be regulated, controlled, and/or directed by one or more processors 154 (controller) in communication with one or more components and/or subsystems such as the chip source section 102, the chip transfer and activation section 104, the bonding section 106, the source chuck 110, the FOUP 112, the transfer robot 126, the activation device 128, the intermediate substrate chuck 130, the plurality of bonding heads 134, the sensors 162, the product substrate chuck 136, the product substrate positioning system including the carriage 142, the plurality of alignment devices 146, the plurality of transfer heads 148, and any microscopes. The processor 154 may operate based on instructions in a computer readable program stored in a non-transitory computer memory 156. The processor 154 may be or include one or more of a CPU, MPU, GPU, ASIC, FPGA, DSP, and a general-purpose computer. The processor 154 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the steps described herein may be executed by the processor 154.

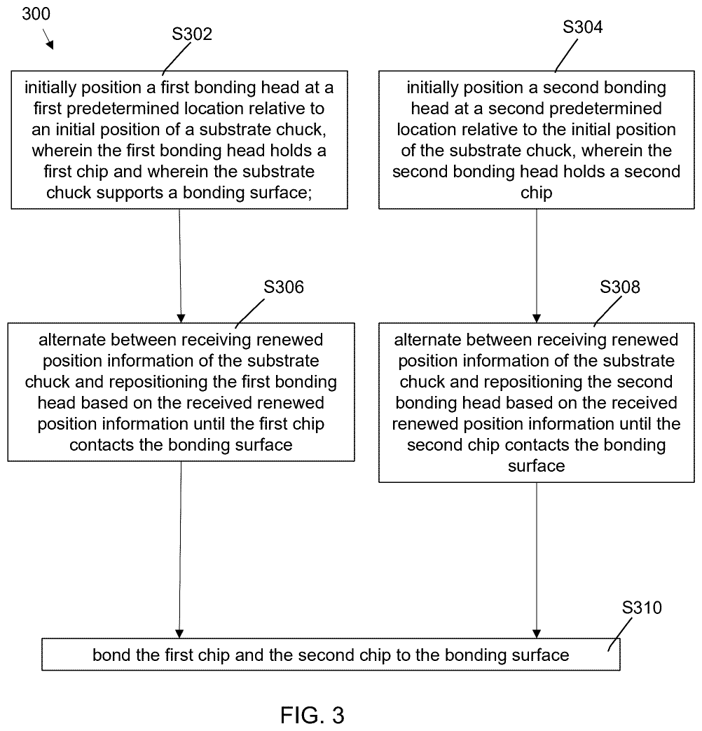

FIG. 3 shows a flowchart of a method for bonding chips 300 using the bonding system 100. The method for bonding chips 300 begins with step S302 where a first bonding head (e.g., the first bonding head BH1) is initially positioned at a first predetermined location relative to an initial position of a substrate chuck (e.g., product substrate chuck 136), wherein the first bonding head holds a first chip (e.g., the first chip 124a) and wherein the substrate chuck supports a bonding surface (e.g., the bonding surface 140). However, several steps may occur prior to the first step shown in FIG. 3 that may also be part of the bonding method. For example, the following additional steps may be performed prior to step S302. First, desired chip information may be received, including what quality of chips are needed and where the chips are to be placed on the bonding surface. The quality of the chips can be defined as maximum clock rate, percentages of functioning transistors at one or more specified clock rates, local cache size, thermal conductivity, and other properties which affect the performance of the chips which can vary depending on the fabrication performance of the chip. After receiving the chip information, if not already activated, the transfer robot 126 may carry a source substrate 114 through the activation device 128 to activate the chips in the manner described above, after which the source substrate 114 is received by the chip bonding section 106. After passing through the activation device 128, with the chips activated, the transfer robot 126 will then carry the source substrate 114 to the second substrate chuck 130 of the chip bonding section 106. In an alternative embodiment, the chips on the source substrate 114 are already activated and are transferred directly to the bonding section 106 from the chip source section 102.

The source substrate 114, having the activated chips 124, may then be chucked to the second substrate chuck 130. Next, once the source substrate 114 having the activated chips 124 has been mounted to the second substrate chuck 130, a microscope may be used to measure the position of the plurality of chips 124. This step may be performed by moving the carriage 142 until the microscope is beneath the plurality of chips 124. If the feedback from the first microscope shows that the certain chips of the plurality of chips 124 are outside of an acceptable amount of error, then a replacement substrate 114 would need to prepared. If the feedback from the microscope shows that the plurality of chips 124 are located at the proper positions within an acceptable amount of error, the method may proceed.

A first set of chips from the source substrate 114 may be then transferred to the plurality of bonding heads 134. This step may be performed by first moving the carriage 142 until the plurality of transfer heads 148 are beneath the plurality of chips 124. The plurality of transfer heads 148 may include the same number of heads with the same pitches as the plurality of bonding heads 134. The plurality of transfer heads 148 are configured to mirror the plurality of bonding heads 134 so that the plurality of transfer heads 148 can transfer up to the same number of chips that the plurality of bonding heads are capable of bonding in a single bonding step. The plurality of transfer heads 148 may pick up a first set of chips from the source substrate 114 by activating a vacuum force, for example. The plurality of transfer heads 148 may maintain the vacuum force while the plurality of transfer heads 148 carrying the first set of chips are moved via the carriage 142 to a position underneath the plurality of bonding heads 134. Either the plurality of transfer heads 148 or the plurality of bonding heads 134 moves toward the other (or both move simultaneously) until the first set of chips are at a position to be transferred to the plurality of bonding heads 134. Once close enough, the vacuum force on the plurality of transfer heads 148 may be terminated and a vacuum force of the plurality of bonding heads 134 may be activated, thereby transferring the first set of chips to the plurality of bonding heads 134. After the chips 124 (first set of chips) have been transferred to the bonding heads, the carriage 142 may be moved to position the product substrate 138 so that the bonding surface 140 arrived at a predetermined location relative to the bonding heads 134 holding the first set of chips. That is, the processor 154 may receive/process information regarding where the chips 124 of the current bonding procedure (first set of chips) should be placed on the bonding surface 140 and based on this information, the processor will cause the carriage 142 to move such that the chips 124 held by the bonding heads 134 are properly located in the X/Y dimensions. The moment after all these steps have been performed, which is just prior to step S302, is the moment shown in FIG. 2. That is, at the moment shown in FIG. 2, each of the bonding heads 134 is holding a chip 124 that is located above the bonding surface 140, and the system ready for the bonding method to proceed.

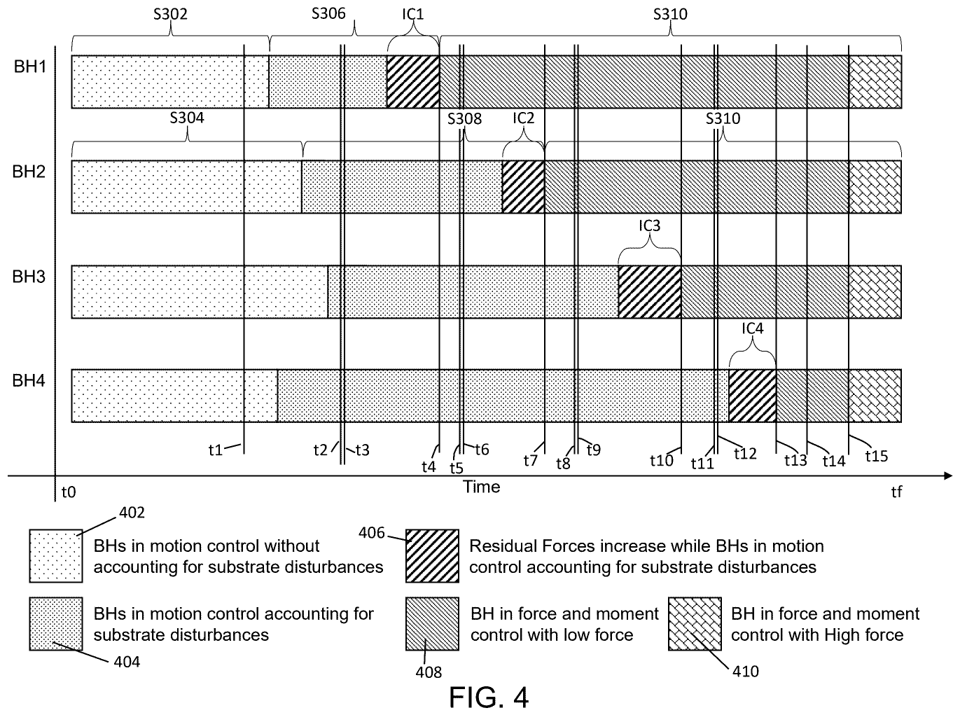

With the above-noted initial steps completed, the bonding method 300 is ready to begin the above-noted step S302 of initially positioning the first bonding head at the first predetermined location of the product chip site (first target chip location 105a), relative to an initial position of the substrate chuck. The method 300 also includes performing a step S304 where a second bonding head (e.g., the second bonding head BH2), holding a second chip (e.g., the chip 124b), is initially positioned at a second predetermined location of the second product chip site (second target chip location 105b), relative to the initial position of the substrate chuck (e.g., the product substrate chuck 136). FIG. 4 shows a control state timing chart indicating the changes in state of four bonding heads during a bonding process, in accordance with an example embodiment. The control state timing chart represents the different control states of each bonding head with different patterns (402, 404, 406, 408, and 410). In FIG. 4 the X-axis represents time where time to is the start of the bonding process and time tf is the end of the bonding process. As shown in FIG. 4, the steps of S302 and S304 may occur during an overlapping period of the bonding process. That is, the first bonding head BH1 and the second bonding head BH2 may be brought to their respective initial predetermined positions based relative to the initial position of the substrate chuck during an overlapping period of time such that at least some portion of step S302 is being performed at the same time as step S304. In another embodiment, the period of time that the first bonding head is positioned may occur at the exact same time period that the second bonding head is positioned, or may occur after or before the second bonding head is positioned. This same principle may be applied to the remaining bonding heads, e.g., a third bonding head BH3 and a fourth bonding head BH4 shown in the example embodiment. The time period in which the bonding heads are brought into the initial predetermined position is represented by the first pattern 402 in the timing chart of FIG. 4. The control state of each of the bonding head stages 120 while it is in the state represented by first pattern 402 is that each of the bonding head stages are in motion control without accounting for disturbances to the position of the product substrate on the product substrate chuck. In the example embodiment of FIG. 4, the time of the initial positioning is different for each bonding head. In other words, the same step corresponding to step S302 and S304 can be performed for all of the bonding heads. As noted in the key in FIG. 4 corresponding to the first pattern 402, during this period of initially positioning the bonding heads, while the bonding heads are moved to the predetermined position taking into account the initial position of the substrate, the bonding heads are moved without considering any renewed position information of the substrate (the renewed position of the substrate being determined from the sensors detecting the change in position of the substrate). Generally, during this initial positioning period, each of the bonding heads are first moved to the desired X/Y coordinate location with the desired Oz orientation of the chip where the chips are to be bonded and then the bonding heads move downward in the Z direction. That is, for most of the initial positioning period, the bonding heads are bringing the chips closer to the bonding surface in the Z direction without altering the position of the chip in the X or Y directions. The predetermined position for each bonding head is predicted in advance based on the desired bonding location, the measured position of the chip on the chip chuck, a desired positioning trajectory, and the measured position of the chip chuck.

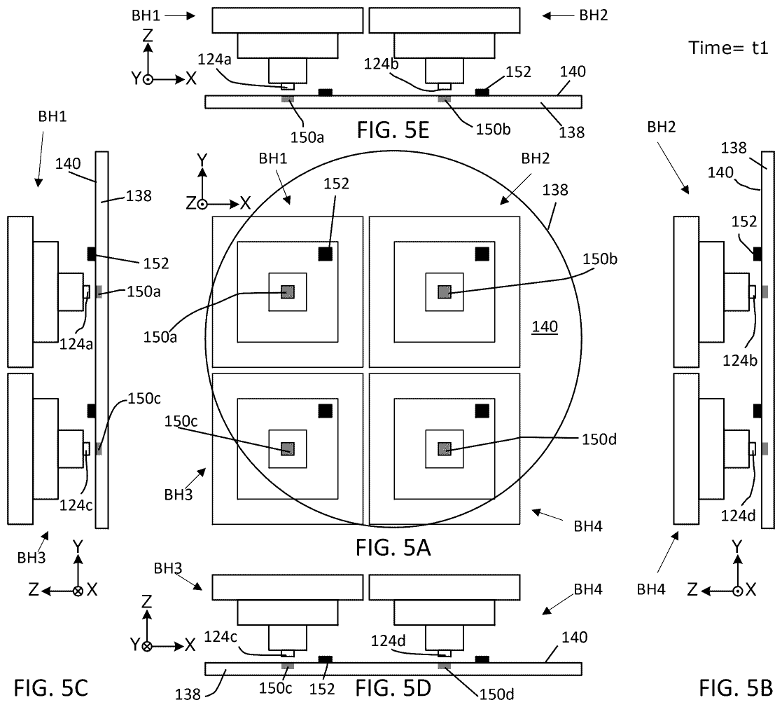

FIGS. 5A to 5E show different schematic views of the bonding heads and substrate positions at a time t1 that occurs within the period in which steps S302 and S304 are being performed. The moment during the bonding process that time t1 occurs is shown in the timing chart of FIG. 4. FIG. 5A is a schematic top view of an example embodiment where four bonding heads are positioned relative to the surface of the substrate at the time t1 of FIG. 4. FIG. 5B is a schematic side view of the bonding heads and substrate in which the Y and Z dimensions are visible, at the same time t1. FIG. 5C is a schematic side view of the opposite side compared to FIG. 5B and also shows the bonding head and substrate such that the Y and Z dimensions are visible. FIG. 5D is a schematic side view of the bonding heads and substrate in which the X and Z dimensions are visible, at the same time t1. FIG. 5E is a schematic side view of the opposite side compared to FIG. 5D and also shows the bonding head and substrate such that the X and Z dimensions are visible. With all of these views, the position of all four of the example embodiment bonding heads (e.g., bonding heads BH1, BH2, BH3, and BH4) at time t1 are visible.

As seen in FIGS. 5A to 5E, at the time t1, the bonding heads BH1, BH2, BH3, BH4 are located at positions above the bonding surface 140 at particular X, Y, and Z dimension positions. That is, during the step of initially positioning the bonding heads based on the initial position of the substrate chuck 138, the carriage 142 has already been moved so that chips 124 are located at the predetermined X/Y coordinate position and Oz orientation above the bonding surface 140 and is in the process of moving downward toward the bonding surface in the Z dimension. Thus, as shown in FIG. 5A, when performing step S302 and step S304, each of the bonding heads BH1, BH2, BH3, BH4 have one of the chips 124a, 124b, 124c, 124d, and the bonding heads BH1, BH2, BH3, BH4 are above the bonding surface 140. This predetermined X and Y dimension location and Oz orientation corresponds to a target X and Y dimension location and Oz orientation on the substrate where it is desired to place the chip. Thus, as seen in FIGS. 5A to 5E, in the example embodiment, there is a first target chip location 150a corresponding to the first bonding head BH1, a second target chip location 150b corresponding to the second bonding head BH2, a third target chip location 150c corresponding to the third bonding head BH3, and a fourth target chip location 150d corresponding to the fourth bonding head BH4. FIGS. 5A to 5E (as well the subsequent figures), also include already bonded chips 152 that would have been bonded in a prior bonding process following the same bonding method 300 described herein.

While all of the bonding heads are facing the substrate in the illustrated embodiment, in some instances not all of the bonding heads are facing the bonding surface. While the benefit of the bonding method 300 is primarily achieved when there are at least two bonding heads actively being used, as long as at least one of the bonding heads is being used, the bonding method 300 can still be performed. In a case where less than all of the available bonding heads are not facing the bonding surface, those not facing the bonding surface will not be actuated and the at least one (preferably two or more) bonding head facing the bonding surface will be actuated.

As the steps of initially positioning the bonding heads proceeds, the bonding heads 134 are actuated such that the chips 124a, 124b, 124c, 124d move in the Z direction toward the bonding surface 140. Additionally, the bonding heads may be bringing down the chips with a predetermined tip and tilt of the chip so that the chip conforms to the substrate. This tip & tilt of each chip could be determined by one or both of the substrate tip-tilt orientation at each target location and each chip's tip-tilt orientation when held by the chip chuck on the bonding head. Once a bonding head reaches a predetermined Z position or within an estimated predetermined gap from the chip held by the chip chuck and an estimate of the substrate plane, while also at the predetermined X/Y positions, the steps of initially positioning the bonding heads based on the initial position for the substrate chuck is completed, i.e., step S302 and step S304, is completed. The same applies to all the other bonding heads present, i.e., a corresponding positioning steps for any other bonding heads are completed. In the example embodiment shown in FIG. 4, the four bonding heads BH1, BH2, BH3, BH4 reach their respective predetermined X, Y, and Z positions at different times. That is, once a particular bonding head reaches the predetermined position for that bonding head, the part of the bonding process where the bonding heads are positioned based on the initial position of the substrate chuck without taking into consideration any renewed position information of the substrate chuck (or of the substrate) is complete. The location in the Z direction when the initial positioning period is complete is determined by a predetermined gap from the substrate plane. Some examples of these gaps may be 5 μm, 10 μm, 20 μm, 30 μm, 50 μm, 100 μm, etc.

After the bonding heads BH1, BH2, BH3, BH4 have reached the predetermined X, Y, and Z location (i.e., completing steps S302/S304), the method proceeds to step S306 and step S308. This transition is shown in FIG. 4 where the first pattern 402 ends and the second pattern 404 begins. In step S306 the method continuously monitors and receives renewed position information of the substrate chuck (or the substrate) and repositions the first bonding head (e.g., bonding head BH1) based on the received renewed position information. In step S306, this continuous monitoring may be implemented by alternating between receiving renewed position information of the substrate chuck (or the substrate) and repositioning the first bonding head (e.g., bonding head BH1) based on the received renewed position information. This alternating between receiving and repositioning occurs until the first chip contacts the bonding surface. That is, step S306 begins after the first bonding head (e.g., bonding head BH1) reaches the predetermined Z location and continues until the first chip (e.g., chip 124a) contacts the bonding surface (e.g., bonding surface 140). Once contact occurs, the step S306 terminates. This period of time is represented by the second pattern 404 of FIG. 4. As stated in the key of FIG. 4, during the period of time represented by the second pattern 404 the bonding head is moved while taking into account changes to the position of the substrate (estimated via the sensed change in position of the substrate chuck). The control state of each of the bonding head stages 120 while it is in the state represented by the second pattern 404 is that each of the bonding head stages are in motion control that is accounting for disturbances to the position of the product substrate 138 on the product substrate chuck 136.

Similarly, in step S308 the method alternates between receiving renewed position information of the substrate chuck (or the substrate) and repositioning the second bonding head (e.g., bonding head BH2) based on the received renewed position information. Receiving renewed position information of the substrate chuck may include one or more sensors measuring the position of substrate chuck at a measurement rate. The processor may perform signal conditioning using analog techniques, digital techniques or both. The signal conditioning may include averaging, time filtering, spatial transforming, etc. The position of each bonding head is controlled by a bonding head position control subsystem. The processor may supply the substrate position to the bonding head position control subsystem at a rate that is less than the measurement rate. Each of the bonding head position control subsystems supplies repositioning instructions to each of the bonding head stages. This alternating between receiving and repositioning occurs until the second chip (e.g., the chip 124b) contacts the bonding surface (e.g., bonding surface 140). That is, step S308 begins after the second bonding head reaches the predetermined Z location and continues until the second chip contacts the bonding surface. Once contact of the chip with the bonding surface occurs, the step S308 terminates. As shown in FIG. 4, the timing of the movement of the bonding heads may be such that step S306 and step S308 start and end at different times, with some overlap. When more bonding heads are present (such as four in the illustrated example embodiment), a corresponding step of alternating between receiving renewed position information of the substrate chuck and repositioning the bonding head based on the received renewed position information may be implemented for each additional bonding head. As also shown in FIG. 4, the duration of step S306 and step S308 may be different. That is, as noted above, the step of alternating between receiving and repositioning continues to occur until the chip contacts the bonding surface. The time it takes for a particular chip to reach the bonding surface varies. Thus, as shown in the example embodiment of FIG. 4, the first chip 124a held by the first bonding head BH1 reaches the bonding surface (at time t4) before the second chip 124b held by the second bonding heads BH2 reaches the bonding surface (at time t7). In this example embodiment, the duration for step S308 is longer than the duration of step S306.

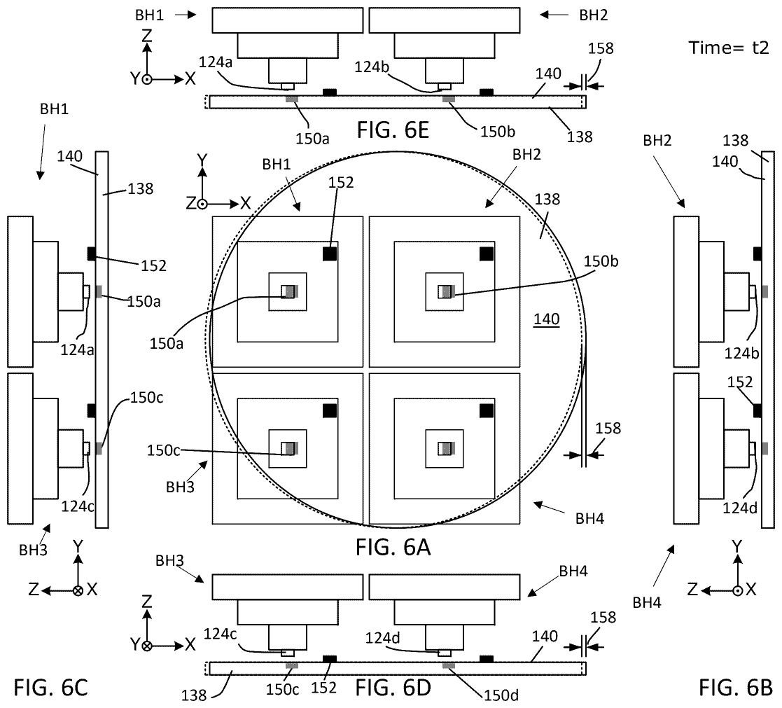

FIGS. 6A to 6E show different schematic views of the bonding heads and substrate positions at time t2 that occurs within the period in which steps S306 and S308 are being performed. That is, as shown in FIG. 4, t2 occurs when all four example bonding heads are in the state represented by pattern 404. FIG. 6A is a schematic top view of the bonding heads and substrate corresponding to the time t2 of FIG. 4. FIG. 6B is a schematic side view of the bonding heads and substrate in which the Y and Z dimensions are visible, at the same time t2. FIG. 6C is a schematic side view of the opposite side compared to FIG. 6B and also shows the bonding head and substrate such that the Y and Z dimensions are visible. FIG. 6D is a schematic side view of the bonding heads and substrate in which the X and Z dimensions are visible, at the same time t2. FIG. 6E is a schematic side view of the opposite side compared to FIG. 6D and also shows the bonding head and substrate such that the X and Z dimensions are visible. With all of these views, the position of all four of the example embodiment bonding heads (e.g., bonding heads BH1, BH2, BH3, and BH4) at time t2 are visible.

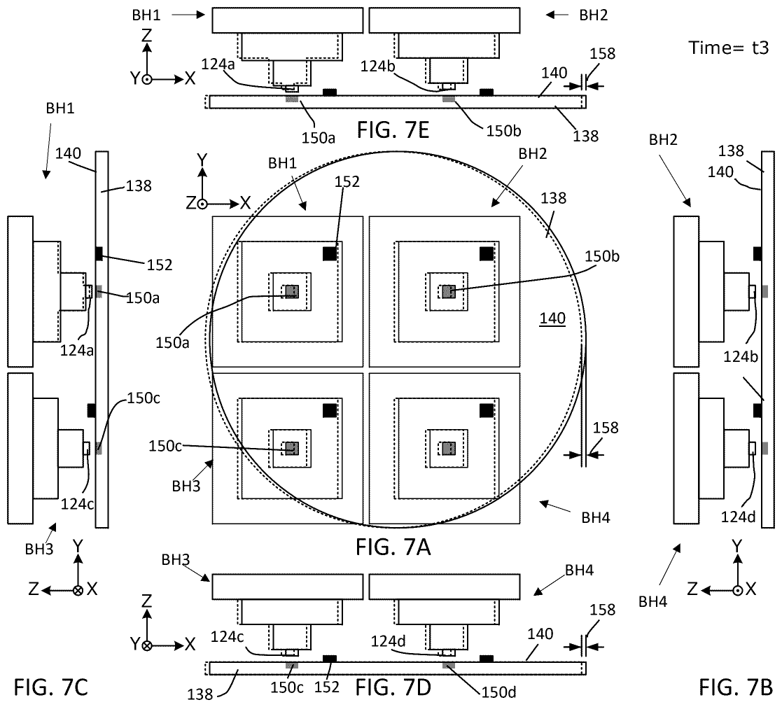

FIGS. 7A to 7E show different schematic views of the bonding heads and substrate positions at time t3 that occurs immediately after the time t2 within the period in which steps S306 and S308 are being performed. That is, as shown in FIG. 4, t3 occurs when all four example bonding heads are in the state represented by pattern 404 right after the time t2. The time duration between t2 and t3 will depend on the responsiveness of the bonding head motion control system and may be on the 2-10 times the sample rate of the substrate position measuring system, which may be 5 ms for example. FIG. 7A is a schematic top view of the bonding heads and substrate corresponding to the time t3 of FIG. 4. FIG. 7B is a schematic side view of the bonding heads and substrate in which the Y and Z dimensions are visible, at the same time t3. FIG. 7C is a schematic side view of the opposite side compared to FIG. 7B and also shows the bonding head and substrate such that the Y and Z dimensions are visible. FIG. 7D is a schematic side view of the bonding heads and substrate in which the X and Z dimensions are visible, at the same time t3. FIG. 7E is a schematic side view of the opposite side compared to FIG. 7D and also shows the bonding head and substrate such that the X and Z dimensions are visible.

Time t2 is a time when there is some movement of the substrate relative to the initial predetermined position and time t3 is a time when the bonding heads are adjusted to compensate for the movement of the substrate. As seen in FIG. 4, in the example embodiment, the times t2 and t3 occur when the position of all four example bonding heads BH1, BH2, BH3, and BH4 are being simultaneously adjusted in response to movement of the substrate. Thus, FIGS. 6A to 6E show an example time t2 when the substrate has moved and FIGS. 7A to 7E show an example time t3 where all of the bonding heads have been repositioned to compensate for the moment of the substrate.

Throughout the figures, the solid lines represent the current location of the components and the dashed line represents the original location of the components. As shown in FIGS. 6A to 6E, at the time t2 a disturbance occurs such that the substrate 138 has as moved in the X dimension. More specifically, as shown in FIGS. 6A, 6D, and 6E, the dashed line of the substrate 138 shows where the substrate previously was located and the solid line shows where the substrate 138 is located after the disturbance, where the disturbance is only in the X dimension and tilting (θy) in the example. Thus, FIGS. 6A, 6D, and 6E show a change in distance 158 in the X dimension while FIGS. 6B and 6C show no change because there was no movement in the Y dimension or the Z dimension at time t2. At the time t2 there has also not yet been an adjustment of the position of any of the bonding heads. Thus, all of the bonding heads BH1, BH2, BH3, and BH4 are shown in the same position as FIGS. 5A to 5E in solid line. FIGS. 6A, 6D, and 6E also show that, prior to adjusting the position of the bonding heads, the target chip locations 150a, 150b, 150c, 150d are no longer aligned with the corresponding chips 124a, 124b, 124c, 124d, in the X dimension because of the movement of the substrate 138 in the X dimension. However, because there is no Y dimension movement in the example, FIGS. 6B and 6C show the target chip locations 150a, 150b, 150c, 150d still aligned with the corresponding chips 124a, 124b, 124c, 124d, in the Y dimension. While only X dimension disturbance has been shown for simplicity, the disturbance can occur in any of the above-noted dimensions, i.e., X, Y, Z, tip, tilt, rotation.

Turning to FIGS. 7A to 7E, as noted above, these figures show the time t3 where the bonding heads have been adjusted to compensate for the movement of the substrate shown in FIGS. 6A to 6E. As above, the dashed line in FIGS. 7A to 7E represent the original location of bonding heads and substrate while the solid lines represent the current position. As shown in FIGS. 7A, 7D, and 7E, all of the bonding heads BH1, BH2, BH3, BH4 in the example embodiment have been moved in the X dimension by the same distance 158 in order to compensate for the movement of the substrate in the X dimension that occurred at time t2. FIG. 7B shows no movement of the bonding heads BH2, BH3 in the Y dimension because in the substrate 138 was only disturbed in the X dimension in the example embodiment. Because each of the bonding heads BH1, BH2, BH3, BH4 have moved in the X dimension by the same amount that the substrate moved in time t2, but in the opposite direction, the chips 124a, 124b, 124c, and 124d are now realigned in the X dimension with the corresponding target chip locations 150a, 150b, 150c, and 150d.

Furthermore, as shown in FIG. 7E, in addition to the adjustment X dimension movement, the bonding head BH1 in the example embodiment moved in the Z dimension toward the bonding surface 140 at the time t3, while the all the other bonding heads (BH2, BH3, BH4) did not change in the Z dimension. As noted above, one benefit of the method being described herein resolves the chip misalignment occurring in the inevitable situation where the chips on the bonding heads will come into contact with the bonding surface at slightly different times (on the nanosecond to millisecond scale). Thus, the figures show different rates of Z dimension change as the bonding method proceeds where BH1 will contact first, followed by BH2, followed by BH3, followed by BH4. This order is chosen as an example embodiment and the method described herein can be applied to any order of contact, and for any number of bonding heads.

The renewed position information of the substrate may be acquired by three or more sensors that measure the position and posture of the substrate chuck. That is, as noted above, the renewed position information can include a change in the X dimension position of the substrate, a change in the Y dimension position of the substrate, a change in the tilt position of the substrate, a change in the tip position for the substrate, and a change in the rotation position of the substrate. The sensors sense the new position in all of these aspects and this information is provided to the controller. The controller can then calculate the necessary correcting adjustment of the bonding heads that are necessary to counteract the position change of the substrate. The sensors may detect the renewed position of the substrate every 0.1-1 ms to 0.5-1 s. A corresponding adjustment of the bonding heads may be made every 0.2 milliseconds (ms) to 10 seconds(s). That is, throughout the duration of steps S306 and S308 the repositioning may be performed every 2 ms to 2 s. This corresponds to 2 to 1000 adjustments of the bonding heads in a bonding process

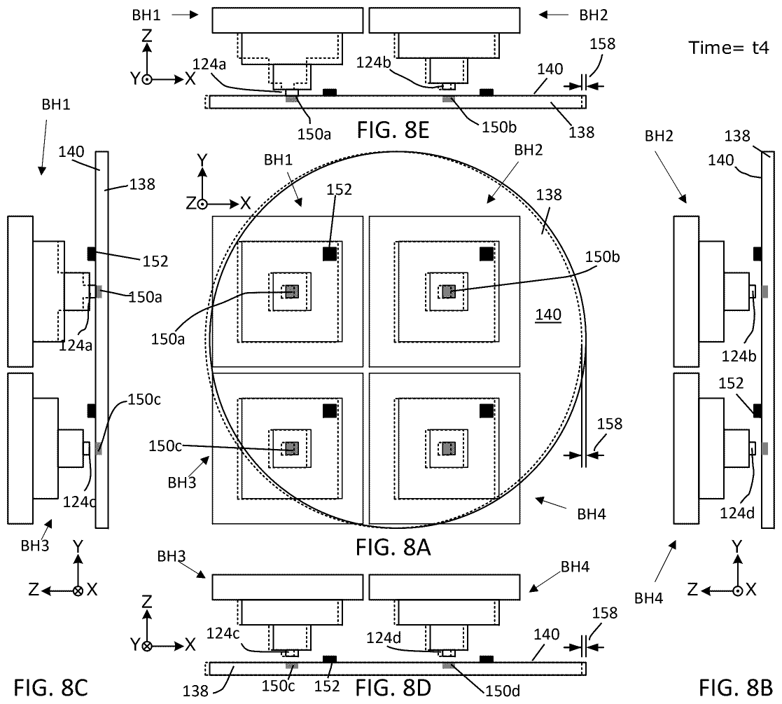

FIGS. 8A to 8E show different schematic views of the bonding heads and substrate positions at time t4 that occurs when one the chips carried by one of the bonding heads comes into contact with the bonding surface 140 with the other chips carried by the other bonding heads have not yet come into contact with the bonding surface. FIG. 8A is a schematic top view of the bonding heads and substrate corresponding to the time t4 of FIG. 4. FIG. 8B is a schematic side view of the bonding heads and substrate in which the Y and Z dimensions are visible, at the same time t4. FIG. 8C is a schematic side view of the opposite side compared to FIG. 8B and also shows the bonding head and substrate such that the Y and Z dimensions are visible. FIG. 8D is a schematic side view of the bonding heads and substrate in which the X and Z dimensions are visible, at the same time t4. FIG. 8E is a schematic side view of the opposite side compared to FIG. 8D and also shows the bonding head and substrate such that the X and Z dimensions are visible.

The control state of each of the bonding head stages 120 while it is in the state represented by the third pattern 406 is that each of the bonding head stages are in motion control that is accounting for disturbances to the position of the product substrate 138 on the product substrate chuck 136 during an initial contact period IC (IC1 for BH1 and IC2 for BH2). During the initial contact period IC, the chip 124 starts to come into contact with the product substrate 138. Friction between the product substrate 138 and the chip 124 reduces the effectiveness of the motion control of the bonding head stage 120 in the plane of the bonding interface. This initial contact period IC can be detected by an increase in the residual force in the Z direction. The start of the initial contact period IC can be difficult to detect in a fast moving bonding system. The end of the initial contact period IC is defined as when the residual force exerted by the bonding head stage 120 in the Z direction is greater than a threshold2. The threshold2 may be determined by the noise limit of the system in which a residual force can be reliably detected. The threshold2 may also be determined based on when the shear stresses due to performing motion control is too high and can cause damage to one or both of the chip 102 and the product substrate. The timing chart of FIG. 4 shows when time t4 occurs at the end of initial contact IC1. In the illustrated example embodiment, at the time t4, the chip carried by the first bonding head BH1 has come into contact with the bonding surface 140, while the chips carried by the other bonding heads BH2, BH3, and BH4 have not yet come into contact with the bonding surface 140. Once a chip comes into reliable contact with the bonding surface 140, the step of alternating between receiving renewed position information of the substrate chuck and repositioning the first bonding head based on the received renewed position information ends. That is, there is no longer any further adjustment of the position of the bonding head that has come into contact with the bonding surface. Thus, in the example embodiment, at the time t4, the position of the first bonding head BH1 will no longer be able to be adjusted and the chip would try to follow the stage position and orientation but no actual relative motion of the chip to the substrate may be possible. Over the duration of the IC1, we expect to see an increase in the total residual Z force and once the total residual Z force exceeds a predetermined threshold (threshold2), the BH1 is determined to be in contact with the product substrate 138 and the BH1 ceases to adjust any position of the chip relative to the product substrate and transitions into force-moment control. In other words, for the particular bonding head whose chip has contacted the bonding surface, the step of alternating between receiving new position information of the substrate chuck and repositioning of the bonding head based on the information is no longer performed. However, at the same time, the position of all of the bonding heads that have not yet come into contact with the bonding surface will continue to be adjusted based on the movement of the substrate. The substrate may continue to move or change its orientation after a chip has come into contact with the bonding surface. Thus, while a bonding head carrying a chip that has already made contact with the bonding surface no longer needs to be adjusted, the remaining bonding heads may continue to need adjustment. When the chip has come into contact is determined by measuring the residual force in the Z direction, which is discussed below in more detail with respect to FIG. 21.

The time t4 shown in FIGS. 8A to 8E is the instant that the first bonding head BH1 begins contacting the surface 140, without any disturbance yet occurring. This is determined when the total residual Z force or total tip-tilt residual moments begin to increase in magnitude due to the initial contact. Thus, in FIGS. 8A to 8E, as compared to time t3 shown in FIGS. 7A to 7E, the only change in position is the Z direction movement of the first bonding head BH1. As also shown in FIG. 4, once the chip carried by one of the bonding heads has contacted the bonding surface (e.g., first chip 124a carried by first bonding head BH1), the bonding head enters a new state represented by the end of the third pattern 406 of FIG. 4. As stated in the key of FIG. 4, during the period of time the initial contact IC1 represented by the third pattern 406 the first bonding head BH1 even though it can no longer be moved (i.e., no longer moved in X, Y, Z, tilt, tip, rotation) but the initial contact force (total residual Z force) or total residual moments over the short time duration IC1 starts to increase in magnitude indicating that the contact of the chip to the substrate is established. Over the duration of the initial contact period IC1, we expect to see an increase in the total residual Z force and once it exceeds a predetermined threshold (Threshold2), the BH1 is determined to be in contact with the substrate and the BH1 ceases to adjust any position of the chip relative to the substrate and transitions into force-moment control.

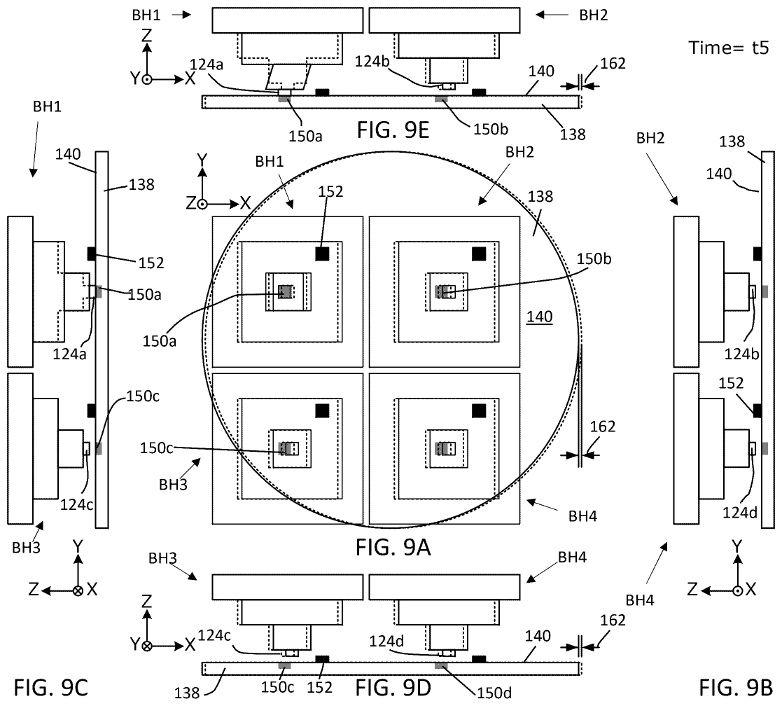

FIGS. 9A to 9G show different schematic views of the bonding heads and substrate positions at time t5 that occurs when there is movement of the substrate after one of the chips has come into contact with the bonding surface, but none of the other chips have yet come into contact with the bonding surface. FIG. 9A is a schematic top view of the bonding heads and substrate corresponding to the time t5 of FIG. 4. FIG. 9B is a schematic side view of the bonding heads and substrate in which the Y and Z dimensions are visible, at the same time t5. FIG. 9C is a schematic side view of the opposite side compared to FIG. 9B and also shows the bonding head and substrate such that the Y and Z dimensions are visible. FIG. 9D is a schematic side view of the bonding heads and substrate in which the X and Z dimensions are visible, at the same time t5. FIG. 9E is a schematic side view of the opposite side compared to FIG. 9D and also shows the bonding head and substrate such that the X and Z dimensions are visible. FIG. 9F is a schematic side view of the bonding heads and substrate in which the Y and Z dimensions are visible, at the same time t5 which shows the product substrate 138 tilting (θy) in a first direction, this tilt may be for example be in a reaction to the first chip 124a contacting the product substrate 138. Note that the chip chuck of BH1 is in a strained state which is caused by the tilt of the substrate and the static state of the chip chuck. In FIG. 9F, the strain is exaggerated so that it is visible in the figure, the actual strain will be very small. FIG. 9G is a schematic side view of the opposite side compared to FIG. 9F showing the tilting of the product substrate.

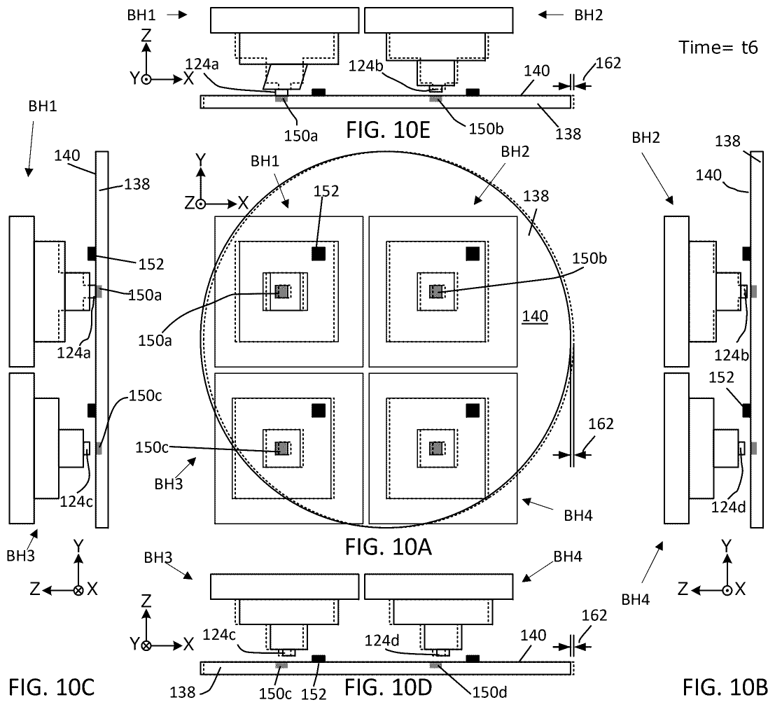

FIGS. 10A to 10G show different schematic views of the bonding heads and substrate positions at time t6 that occurs when the bonding heads with chips that have not yet contacted the bonding surface are moved in response to the movement of the substrate that occurs at time t5. FIG. 10A is a schematic top view of the bonding heads and substrate corresponding to the time t6 of FIG. 4. FIG. 10B is a schematic side view of the bonding heads and substrate in which the Y and Z dimensions are visible, at the same time t6. FIG. 10C is a schematic side view of the opposite side compared to FIG. 10B and also shows the bonding head and substrate such that the Y and Z dimensions are visible. FIG. 10D is a schematic side view of the bonding heads and substrate in which the X and Z dimensions are visible, at the same time t6. FIG. 10E is a schematic side view of the opposite side compared to FIG. 10D and also shows the bonding head and substrate such that the X and Z dimensions are visible. FIG. 10F is a schematic side view of the bonding heads and substrate in which the Y and Z dimensions are visible, at the same time t6 which shows the product substrate 138 still tilted in the first direction, the bonding head stages 120 of the bonding head (BH2, BH3, BH4) that are not in contact with the product substrate will tilt the chip chuck in response to the tilting of the product substrate. FIG. 10G is a schematic side view of the opposite side compared to FIG. 10F showing the bonding head stages 120 of the bonding heads BH3 and BH4 tilting the chip chucks.

The timing chart of FIG. 4 shows when times t5 and t6 occur. In the illustrated example embodiment, at time t5, the substrate 138 moves. The response of the bonding heads to the movement of the substrate occurs at time t6. Because the chips (e.g., 124b, 124c, 124d) carried by the bonding heads (e.g., BH2, BH3, and BH4) that have not yet come into contact with the bonding surface 140, at time t6, the step of adjusting the position of the bonding heads BH2, BH3, BH4 is still performed to counteract the movement of the substrate that occurred at time t5. However, because the chip 124a carried by the bonding head BH1 already came into contact with the bonding surface at time t4, the bonding head BH1 is not moved at time t6 in response to the movement of substrate that occurred at time t5. The simultaneous states of the bonding heads are best shown in FIG. 4. As seen in FIG. 4, at the end of the time t4, the first bonding head BH1 is at the end of the state represented by the third pattern 406 where there is no movement of bonding head, during the initial contact period IC1 there maybe an increase in total residual Z-force (force that the actuators of the bonding head stage 102 of BH1 supply so that the chip conforms to the substrate) for BH1 as it is establishing contact. This residual Z-force excludes the force needed to overcome the elastic forces of the springs, flexures, etc. aiding the motion of BH in Z direction by the bonding head stage. As also shown in FIG. 4 at the same times t5 and t6, the second bonding head BH2, the third bonding head BH3, and the fourth bonding head BH4 are all still in the state represented by the second pattern 404. That is, each of the bonding heads BH2, BH3, BH4 are still in a state where the bonding head is moved to account for the movement of the substrate. In short, at time t5 the substrate moves, and at time t6 only bonding heads whose chips have not yet contacted the substrate are moved to account for the movement of the substrate.

FIGS. 9A to 9G show what happens at time t5, when the movement of the substrate occurs, but before time t6 where the corresponding corrective action is applied to the bonding heads. As best seen in FIGS. 9A, 9D, and 9E the substrate 138 has moved by a distance 162 relative to the initial position of FIGS. 5A to 5E. In the illustrated example embodiments, the substrate has moved in the X direction or tilting (θy) around the y axis. However, the substrate may move in X, Y, Z direction or may tip, tilt, or rotate. Each of the movements may occur alone or in any combination of movements including instances where all six movements happen at once. As seen in FIGS. 9A, 9D, 9E, and 9G, because of the movement of the substrate 138 in the X direction and tilting (θy) around the y axis, the chips that have not yet come into contact with the bonding surface are no longer aligned with the target bonding location 150. In the illustrated embodiment, the second chip 124b, the third chip 124c, and the fourth chip 124d are no longer aligned with the respective target locations 150b, 150c, 150d. However, the chip that already made contact with the bonding surface remains at the correct target location despite the movement of the substrate because the position of the chip became fixed after making contact. Thus, in the illustrated embodiment, the first chip 124a is still aligned with the target location 150a. Practically, as one of the BH1 contacts the substrate at a location, this initial contact can induce a tip-tilt motion of the substrate as the substrate's tip-tilt rotation axes can be at a plane different from the substrate plane. This tip-tilt motion can manifest as position errors, posture errors or both as observed by the substrate stage position sensors. These position errors as observed by the substrate stage sensors can then be transformed and supplied as offsets to the bonding head controllers that have not yet made contact with the substrate. As best shown in FIG. 9F the first chip 1234a contacting the product substrate induces a tilt of the product substrate 138.

FIGS. 10A to 10G show what happens at time t6, when the corresponding corrective action is applied to the bonding heads whose chips have not yet contacted the bonding surface. In the illustrated example embodiment, the first bonding head BH1 is no longer repositioned based on the movement of the substrate. Thus, as seen when comparing FIGS. 10A and 10E with FIGS. 9A and 9E there is no change in the position of the bonding head BH1 in the X direction despite the movement of the substrate in the X direction at time t5. As noted above, once a chip comes into contact with the bonding surface 140, the step of alternating between receiving renewed position information of the substrate chuck and repositioning the first bonding head based on the received renewed position information ends. However, as best seen in FIGS. 10A, 10D, and 10E, the remaining bonding heads BH2, BH3, BH4 have all been moved in the X dimension by the same distance 158 that the substrate moved. Thus, as shown in FIG. 4, at time t6, each of the bonding heads BH2, BH3, BH4 are still in the state represented by pattern 404 where the bonding heads are moved to account for movement of the substrate. At the same time, in the illustrated example embodiment, as seen in FIG. 10B, the second bonding head BH2 has moved downwardly in the Z direction closer to the bonding surface, while the third bonding head BH3 and the fourth bonding head BH4 have not.

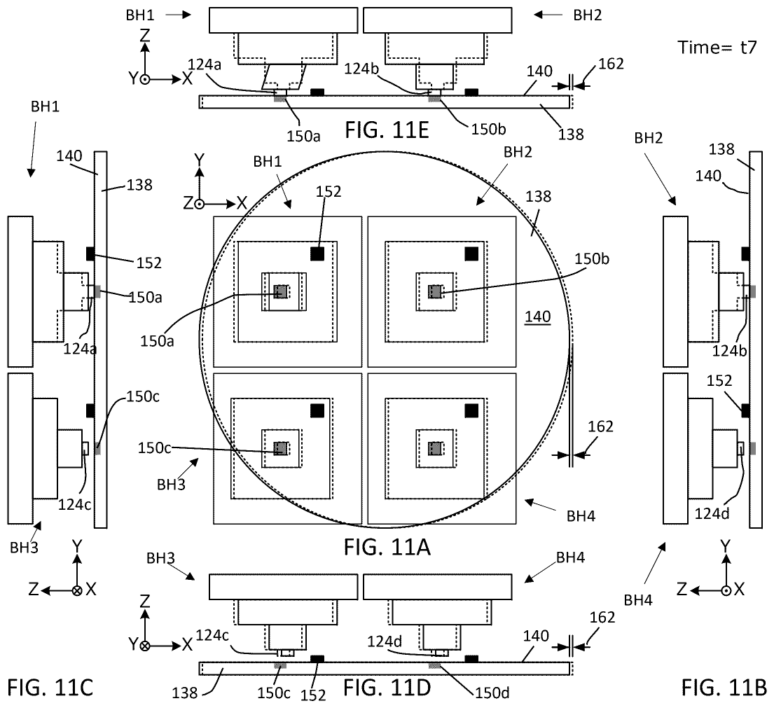

FIGS. 11A to 11G show different schematic views of the bonding heads and substrate positions at time t7 that occurs when a second chip of the chips carried by one of the bonding heads comes into contact with the bonding surface 140, while other chips carried by other bonding heads have not yet come into contact with the bonding surface. FIG. 11A is a schematic top view of the bonding heads and substrate corresponding to the time t7 of FIG. 4. FIG. 11B is a schematic side view of the bonding heads and substrate in which the Y and Z dimensions are visible, at the same time t7. FIG. 11C is a schematic side view of the opposite side compared to FIG. 11B and also shows the bonding head and substrate such that the Y and Z dimensions are visible. FIG. 11D is a schematic side view of the bonding heads and substrate in which the X and Z dimensions are visible, at the same time t7. FIG. 11E is a schematic side view of the opposite side compared to FIG. 11D and also shows the bonding head and substrate such that the X and Z dimensions are visible. FIGS. 11F-G are schematic side views of the bonding heads and substrate in which the Y and Z dimensions are visible, at the same time t7 which shows the product substrate 138 tilted (0y) in a first direction, while BH2 contacts the product substrate 138.

The timing chart of FIG. 4 shows when time t7 occurs at the end of the initial contact period IC2. In the illustrated example embodiment, at the time t7, the chip carried by the second bonding head BH2 has now come into contact with the bonding surface 140, while the chips 124c, 124d carried by the bonding heads BH3 and BH4 have not yet come into contact with the bonding surface 140. The chip 124a carried by the first bonding head BH1 previously came into contact with the bonding surface. As with the first chip 124a, once the second chip 124b comes into contact with the bonding surface 140, the step of alternating between receiving renewed position information of the substrate chuck and repositioning the second bonding head based on the received renewed position information ends. That is, there is no longer any further adjustment of the position of the second bonding head BH2 whose chip has come into contact with the bonding surface. Thus, in the example embodiment, at the time t7, the position of the second bonding head BH2 will no longer be adjusted even when the substrate moves. However, at the same time, the position of all of the bonding heads that have not yet come into contact with the bonding surface (e.g., the third bonding head BH3 and the fourth bonding head BH4) will continue to be adjusted based on the movement of the substrate.

More specifically, the time t7 shown in FIGS. 11A to 11G is the instant that the second bonding head BH2 contacts the surface 140, without any disturbance yet occurring. Thus, in FIGS. 11A to 11E, as compared to time t6 shown in FIGS. 10A to 10E, the only change in position is the Z direction movement of the second bonding head BH2. There is no X/Y movement of any bonding heads at this particular time t7 relative to time t6 because there has also been no movement of the substrate, in the illustrated example embodiment. As also shown in FIG. 4, once the second chip 124b carried by the second bonding head BH2 has contacted the bonding surface, the second bonding head BH2 exits the state represented by the third pattern 406 of FIG. 4. As stated in the key of FIG. 4, during the period of time represented by the third pattern 406 the second bonding head BH2 is still being moved but the residual force imparted by the bonding head increases until a residual force that is above threshold2 is measured. As also shown in FIG. 4, prior to the time t7, the state of the first bonding head BH1 switched from the state represented by the third pattern 406 to a state represented by the fourth pattern 408. As stated in the key of FIG. 4, during the period of time represented by the fourth pattern 408, there is no movement of the bonding head, but a constant low force is maintained in the Z direction. The control state of each of the bonding head stages 120 while it is in the state represented by fourth pattern 408 is that each of the bonding head stages are in low constant force in the z direction and low to zero moment control without accounting for disturbances to the position of the product substrate on the product substrate chuck. Disturbances to the position of the product substrate are very small and can be absorbed as strain in one or both of the chip chuck 122 and parts of the bonding head stage 120. The BH1 has switched from position control to a force-moment control in Z-tip-tilt and the BH1 holds the last set of currents applied at the end of IC1 and S306 to hold the last position in X, Y and Oz. In Z-tip-tilt direction, force-moment control means that forces that the actuators of the bonding head stage 120 supply to chip chuck in Z direction and moments, Mx and My are now controlled. This may entail following a reference force trajectory for total Z-force and regulating the moments in Mx, My to 0, a low constant value, or a low constant average value. The moment Mx is the x component of the moment of force that the bonding head stage applies to chip chuck. The moment My is the y component of the moment of force that the bonding head stage 120 applies to chip chuck 122. A total force trajectory in the Z direction is supplied to the BH1 which is held at a small force magnitude. In an embodiment the small force magnitude in the Z direction may be 0.1 N, 0.5 N, 1 N, 2 N, 5 N. The force trajectory in the Z direction may be a series of values that eventually reach the small force trajectory. The force trajectory may be critically damped, overdamped, or underdamped. This relatively low force (small force magnitude) is a sufficient enough force to maintain an incomplete bond of the chip and the bonding surface, but not enough force to fully bond the entire surface area of the chip to the bonding surface.

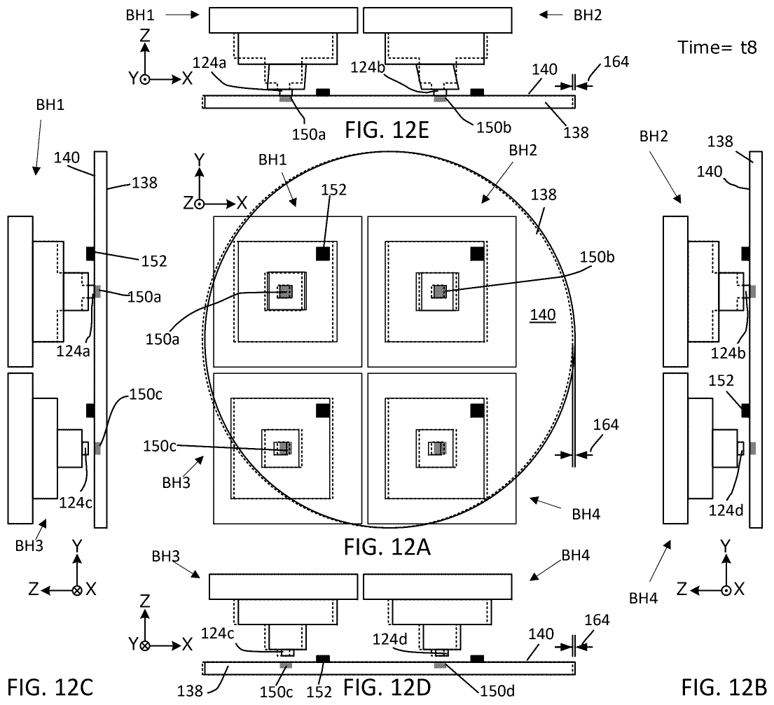

FIGS. 12A to 12G show different schematic views of the bonding heads and substrate positions at time t8 that occurs when there is movement of the substrate after two of the chips have come into contact with the bonding surface, but none of the other chips have yet come into contact with the bonding surface. FIG. 12A is a schematic top view of the bonding heads and substrate corresponding to the time t8 of FIG. 4. FIG. 12B is a schematic side view of the bonding heads and substrate in which the Y and Z dimensions are visible, at the same time t8. FIG. 12C is a schematic side view of the opposite side compared to FIG. 12B and also shows the bonding head and substrate such that the Y and Z dimensions are visible. FIG. 12D is a schematic side view of the bonding heads and substrate in which the X and Z dimensions are visible, at the same time t8. FIG. 12E is a schematic side view of the opposite side compared to FIG. 12D and also shows the bonding head and substrate such that the X and Z dimensions are visible. FIGS. 12F-G are schematic side views of the bonding heads and substrate in which the Y and Z dimensions are visible, at the same time t8 which shows the product substrate 138 tilted (θy) in a second direction, after BH2 contacts the product substrate 138 inducing a tilt θy. Note that the chip chucks of BH1 and BH2 are in a strained state which is caused by the tilt of the substrate and the static state of the chip chuck. In FIG. 12F, the strain is exaggerated so that it is visible in the figure, the actual strain will be very small.

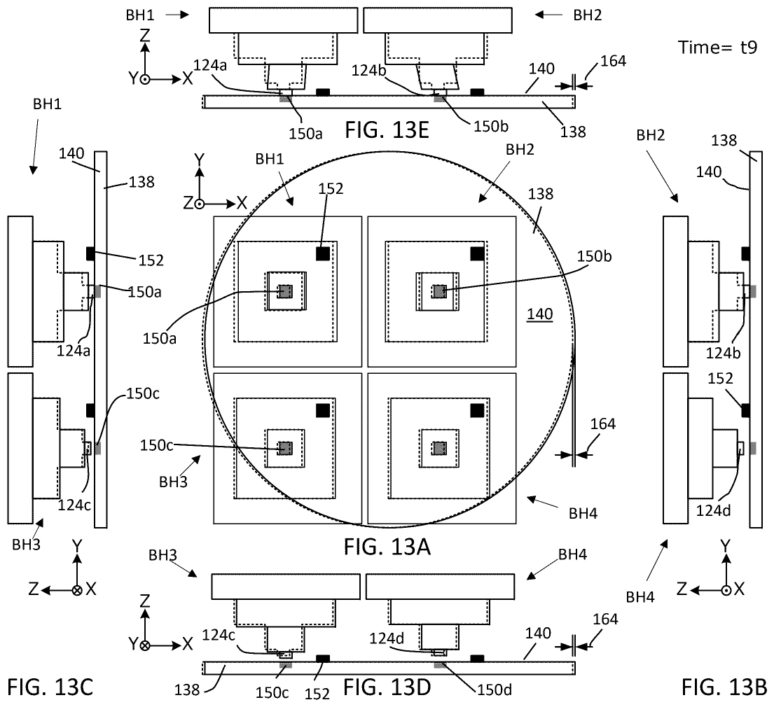

FIGS. 13A to 13G show different schematic views of the bonding heads and substrate positions at time t9 that occurs when the bonding heads with chips that have not yet contacted the bonding surface are moved in response to the movement of the substrate that occurs at time t8. FIG. 13A is a schematic top view of the bonding heads and substrate corresponding to the time t9 of FIG. 4. FIG. 13B is a schematic side view of the bonding heads and substrate in which the Y and Z dimensions are visible, at the same time t9. FIG. 13C is a schematic side view of the opposite side compared to FIG. 13B and also shows the bonding head and substrate such that the Y and Z dimensions are visible. FIG. 13D is a schematic side view of the bonding heads and substrate in which the X and Z dimensions are visible, at the same time t9. FIG. 13E is a schematic side view of the opposite side compared to FIG. 13D and also shows the bonding head and substrate such that the X and Z dimensions are visible. FIGS. 13F-G are schematic side views of the bonding heads and substrate in which the Y and Z dimensions are visible, at the same time t9 which shows the product substrate 138 tilted (θy) in a second direction. FIG. 13G shows the bonding head stages of the bonding heads (BH1 and BH2) not in contact with the product substrate tilting the chip chuck in response to the tilting of the product substrate.

The timing chart of FIG. 4 shows when times t8 and t9 occur. In the illustrated example embodiment, at time t8, the substrate 138 moves. The response of the bonding heads to the movement of the substrate occurs at time t9. Because the chips (e.g., 124c, 124d) carried by the bonding heads (e.g., BH3, BH4) that have not yet come into contact with the bonding surface 140, at time t9, the step of adjusting the position of the bonding heads BH3, BH4 is still performed to counteract the movement of the substrate that occurred at time t8. However, because the chip 124a carried by the bonding head BH1 and the chip 124b carried by the second bonding head BH2 already came into contact with the bonding surface, the bonding head BH1 and the bonding head BH2 are not moved at time t9 in response to the movement of substrate that occurred at time t8. The simultaneous states of the bonding heads are best shown in FIG. 4. As seen in FIG. 4, at the times t8 and t9, the first bonding head BH1 is still in the state represented by the fourth pattern 408 where there is no movement of bonding head and a low amount of constant force in the Z direction is applied. As also shown in FIG. 4 at the time t7, the second bonding head BH2 is at the end of the state represented by the third pattern 406 where the bonding head is still in motion control but the amount of residual force in the Z direction is changing due to initial contact. Finally, FIG. 4 shows that the third bonding head BH3 and the fourth bonding head BH4 are still in the state represented by the second pattern 404. That is, the bonding heads BH3, BH4 are still in a state where the bonding head is moved to account for the movement of the substrate. In short, at time 18 the substrate moves, and at time t9 only bonding heads whose chips have not yet contacted the substrate are moved to account for the movement of the substrate.

FIGS. 12A to 12G show what happens at time t8, when the movement of the substrate occurs, but before time t9 where the corresponding corrective action is applied to the bonding heads BH3, BH4. As best seen in FIGS. 12A, 12D, and 12E the substrate 138 has moved by a distance 164 relative to the initial position of FIGS. 5A to 5E. In FIGS. 12F-G showing a tilt of the product substrate. In the illustrated example embodiment, the substrate has moved only in the X direction and the tilt direction. However, the substrate may move in X, Y, Z direction or may tip, tilt, or rotate. Each of the movements may occur alone or in any combination of movements including instances where all six movements happen at once. As seen in FIGS. 12A and 12D, because of the movement of the substrate 138 in the X direction, the chips that have not yet come into contact with the bonding surface are no longer aligned with the target bonding location 150. In the illustrated embodiments, the third chip 124c and the fourth chip 124d are no longer aligned with the respective target locations 150c, 150d. However, the chips that already made contact with the bonding surface remains at the correct target location despite the movement of the substrate because the position of the chip became fixed after making contact. Thus, in the illustrated embodiment, the first chip 124a and the second chip 124b is still aligned with the target location 150a, 150b.

FIGS. 13A to 13G show what happens at time t9, when the corresponding corrective action is applied to the bonding heads whose chips have not yet contacted the bonding surface. In the illustrated example embodiment, the first bonding head BH1 and the second bonding head BH2 are no longer repositioned based on the movement of the substrate. Thus, as seen when comparing FIGS. 13A and 13E with FIGS. 12A and 12E there is no change in the position of the bonding heads BH1, BH2 in the X direction despite the movement of the substrate in the X direction at time t8. As noted above, once a chip comes into contact with the bonding surface 140, the step of alternating between receiving renewed position information of the substrate chuck and repositioning the bonding head (e.g., bonding head BH1 and bonding head BH2) based on the received renewed position information ends. However, as best seen in FIGS. 13A and 13D, the remaining bonding heads BH3, BH4 have all been moved in the X dimension by the same distance 158 that the substrate moved. Thus, as shown in FIG. 4, at time t9, each of the bonding heads BH3, BH4 are still in the state represented by pattern 404 where the bonding heads are moved to account for movement of the substrate. At the same time, in the illustrated example embodiment, as seen in FIG. 13C, the third bonding head BH3 has moved downwardly in the Z direction closer to the bonding surface, while the fourth bonding head BH4 has not. As seen in FIG. 13G the bonding head stages 120 of the bonding heads BH3 and BH4 tilt the chip chucks 122.

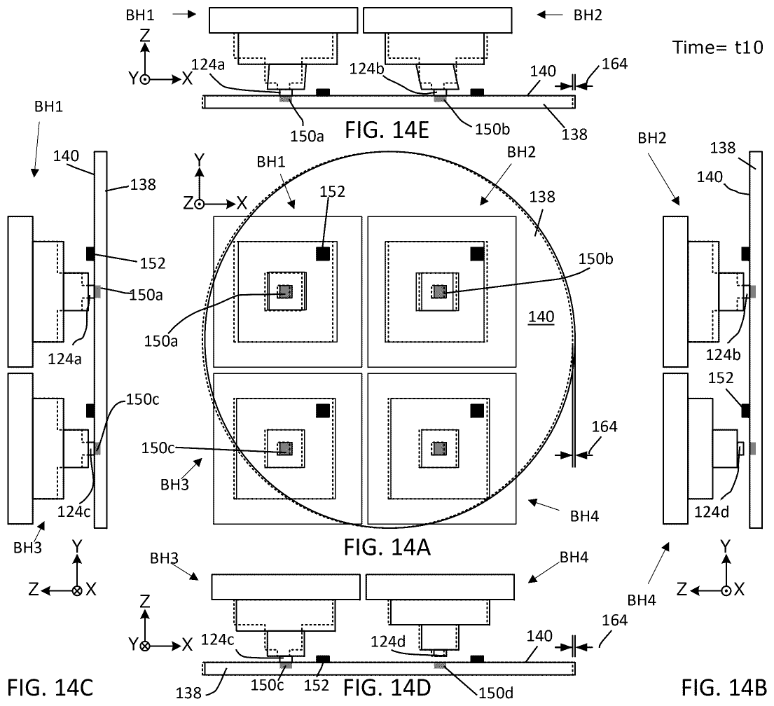

FIGS. 14A to 14G show different schematic views of the bonding heads and substrate positions at time t10 that occurs when a third chip 124c carried by the third bonding head BH3 comes into contact with the bonding surface 140, while the remaining fourth chip 124d carried by the fourth bonding head BH4 has not yet come into contact with the bonding surface. FIG. 14A is a schematic top view of the bonding heads and substrate corresponding to the time t10 of FIG. 4. FIG. 14B is a schematic side view of the bonding heads and substrate in which the Y and Z dimensions are visible, at the same time t10. FIG. 14C is a schematic side view of the opposite side compared to FIG. 14B and also shows the bonding head and substrate such that the Y and Z dimensions are visible. FIG. 14D is a schematic side view of the bonding heads and substrate in which the X and Z dimensions are visible, at the same time t10. FIG. 14E is a schematic side view of the opposite side compared to FIG. 14D and also shows the bonding head and substrate such that the X and Z dimensions are visible. FIGS. 14F-G are schematic side views of the bonding heads and substrate in which the Y and Z dimensions are visible, at the same time t10 which shows the product substrate 138 tilted (θy) in a second direction. FIG. 14G shows bonding head Bh3 coming into contact with the product stage.

The timing chart of FIG. 4 shows when time t10 occurs. In the illustrated example embodiment, at the time t10, the chip carried by the third bonding head BH3 has now come into contact with the bonding surface 140, while the chip 124d carried by the fourth bonding head has not yet come into contact with the bonding surface 140. The chip 124a carried by the first bonding head BH1 and the chip 124b carried by the second bonding head BH2 previously came into contact with the bonding surface. As with the first chip 124a and the second chip 124b, once the third chip 124c comes into contact with the bonding surface 140, the step of alternating between receiving renewed position information of the substrate chuck and repositioning the third bonding head based BH3 on the received renewed position information ends. That is, there is no longer any further adjustment of the position of the third bonding head BH3 whose chip has come into contact with the bonding surface. Thus, in the example embodiment, at the time t10, the position of the third bonding head BH3 will no longer be adjusted even when the substrate moves. However, at the same time, the position of the remaining bonding head BH4 that has not yet come into contact with the bonding surface will continue to be adjusted based on the movement of the substrate.

More specifically, the time t10 shown in FIGS. 14A to 14G is the instant that the third bonding head BH3 contacts the surface 140, without any disturbance yet occurring. Thus, in FIGS. 13A to 13E, as compared to time t9 shown in FIGS. 13A to 13E, the only change in position is the Z direction movement of the third bonding head BH3. There is no X/Y movement of any bonding heads at this particular time t10 relative to time t9 because there has also been no movement of the substrate, in the illustrated example embodiment. As also shown in FIG. 4, once the third chip 124c carried by the third bonding head BH3 starts to contact the bonding surface, the third bonding head BH3 enters a new state represented by the third pattern 406 of FIG. 4. That is, during the initial contact period IC3 of time represented by the third pattern 406 the third bonding head BH3 is still moves but the residual force imparted by the bonding head starts to increase. As also shown in FIG. 4, just prior to the time t10, the state of the first bonding head BH1 is still in the state represented by the fourth pattern 408 and the second bonding head BH2 has also entered into the state represented by the fourth pattern 408. As noted above, during the period of time represented by the fourth pattern 408, there is still no movement of the bonding head, but a constant low force is maintained in the Z direction. Thus, at the time t10 both the first bonding head BH1 and the second bonding head BH3 are imparting a relatively low force to their respective chips that is a sufficient enough force to maintain an incomplete bond of the chip and the bonding surface, but not enough force to fully bond the entire surface area of the chip to the bonding surface.

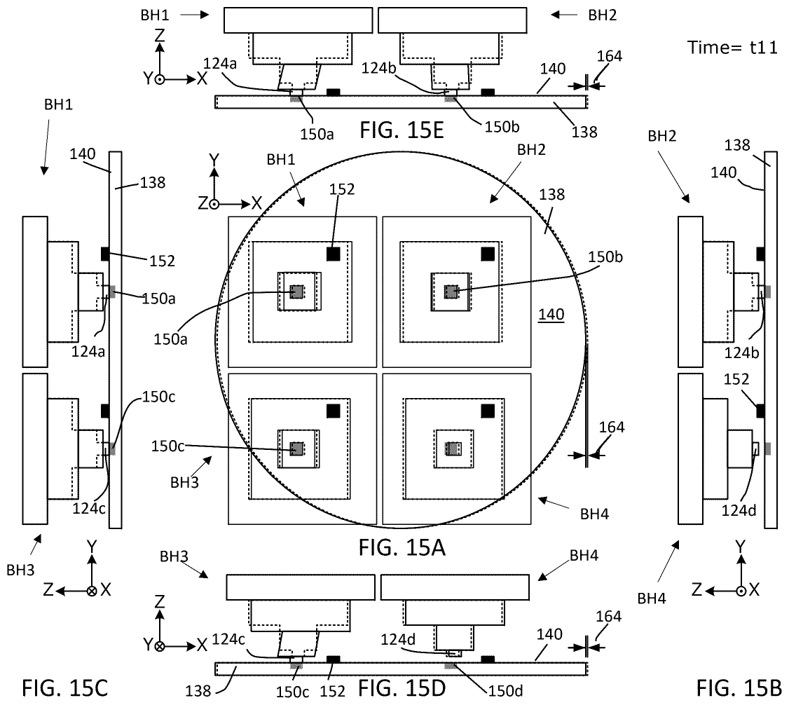

FIGS. 15A to 15G show different schematic views of the bonding heads and substrate positions at time t11 that occurs when there is movement of the substrate after three of the chips (124a, 124b, 124c) have come into contact with the bonding surface, but the fourth chip 124d has not yet come into contact with the bonding surface. FIG. 15A is a schematic top view of the bonding heads and substrate corresponding to the time t11 of FIG. 4. FIG. 15B is a schematic side view of the bonding heads and substrate in which the Y and Z dimensions are visible, at the same time t11. FIG. 15C is a schematic side view of the opposite side compared to FIG. 15B and also shows the bonding head and substrate such that the Y and Z dimensions are visible. FIG. 15D is a schematic side view of the bonding heads and substrate in which the X and Z dimensions are visible, at the same time t11. FIG. 15E is a schematic side view of the opposite side compared to FIG. 15D and also shows the bonding head and substrate such that the X and Z dimensions are visible. FIGS. 15F-G are schematic side views of the bonding heads and substrate in which the Y and Z dimensions are visible, at the same time t11 which shows the product substrate 138 tilted (θy) in a first direction in response to the third chip 124c contacting the product substrate 138.

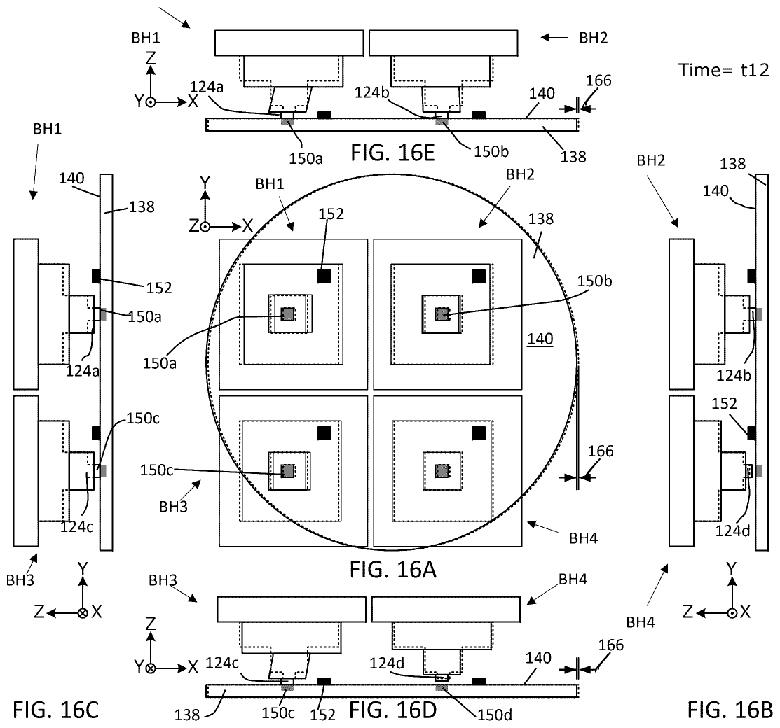

FIGS. 16A to 16G show different schematic views of the bonding heads and substrate positions at time t12 that occurs when the fourth bonding head BH4 with the fourth chip 124d that has not yet contacted the bonding surface is moved in response to the movement of the substrate that occurs at time t11. FIG. 16A is a schematic top view of the bonding heads and substrate corresponding to the time t12 of FIG. 4. FIG. 16B is a schematic side view of the bonding heads and substrate in which the Y and Z dimensions are visible, at the same time t12. FIG. 16C is a schematic side view of the opposite side compared to FIG. 16B and also shows the bonding head and substrate such that the Y and Z dimensions are visible. FIG. 16D is a schematic side view of the bonding heads and substrate in which the X and Z dimensions are visible, at the same time t12. FIG. 16E is a schematic side view of the opposite side compared to FIG. 16D and also shows the bonding head and substrate such that the X and Z dimensions are visible. FIGS. 16F-G are schematic side views of the bonding heads and substrate in which the Y and Z dimensions are visible, at the same time t12 which shows the product substrate 138 tilted (θy) in a first direction and the bonding head stage of the bonding head stages 120 of the fourth bonding head moving the chip chuck to align with the tilt of the product substrate.

The timing chart of FIG. 4 shows when times t11 and t12 occur. In the illustrated example embodiment, at time t11, the substrate 138 moves. The response of the bonding head BH4 to the movement of the substrate occurs at time t12. Because the chip 124d carried by the fourth bonding head BH4 has not yet come into contact with the bonding surface 140, at time t12, the step of adjusting the position of the bonding head BH4 is still performed to counteract the movement of the substrate that occurred at time t11. However, because the chip 124a carried by the bonding head BH1, the chip 124b carried by the second bonding head BH2, and the chip 124c carried by the third bonding head BH3 already came into contact with the bonding surface, the bonding heads BH1, BH2, BH3 are not moved at time t12 in response to the movement of substrate that occurred at time t11. The simultaneous states of the bonding heads are best shown in FIG. 4. As seen in FIG. 4, at the times t11 and t12, the first bonding head BH1 and the second bonding head BH2 are still in the state represented by the fourth pattern 408 where there is no movement of bonding head and a low amount of constant force in the Z direction is applied. As also shown in FIG. 4 at the time t10, the third bonding head BH3 is at the end of the state represented by the third pattern 406 where the bonding head still moves but the amount of residual force in the Z direction is increasing. Finally, FIG. 4 shows that the fourth bonding head BH4 is still in the state represented by the second pattern 404. That is, the bonding head BH4 is still in a state where the bonding head is moved to account for the movement of the substrate. In short, at time t11 the substrate moves, and at time t12 only the fourth bonding head BH4 is moved to account for the movement of the substrate because the fourth bonding head BH4 is the only bonding head left whose chip has not yet contacted the substrate.

FIGS. 15A to 15G show what happens at time t11, when the movement of the substrate occurs, but before time t12 where the corresponding corrective action is applied to the fourth bonding head BH4. As best seen in FIGS. 15A, 15D, and 15E the substrate 138 has moved by a distance 166 relative to the initial position of FIGS. 5A to 5E. In the illustrated example embodiment, the substrate has moved only in the X direction and the tilt direction θy. However, the substrate may move in X, Y, Z direction or may tip, tilt, or rotate. Each of the movements may occur alone or in any combination of movements including instances where all six movements happen at once. As seen in FIGS. 15A and 15D, because of the movement of the substrate 138 in the X direction, the fourth chip 124d having not yet come into contact with the bonding surface is no longer aligned with the target bonding location 150d. However, the chips that already made contact with the bonding surface remain at the correct target locations despite the movement of the substrate because the position of the chip became fixed after making contact. Thus, in the illustrated embodiment, the first chip 124a, the second chip 124b, and the third chip 124c are still aligned with the target locations 150a, 150b, 150c.

FIGS. 16A to 16G show what happens at time t12, when the corresponding corrective action is applied to the fourth bonding head BH4 whose chip 124d has not yet contacted the bonding surface. In the illustrated example embodiment, the first bonding head BH1, the second bonding head BH2, and the third bonding head BH3 are no longer repositioned based on the movement of the substrate. Thus, as seen when comparing FIGS. 16A, 16D, and 16E with FIGS. 15A, 15D, and 15E, there is no change in the position of the bonding heads BH1, BH2, BH3 in the X direction despite the movement of the substrate in the X direction at time t11. As noted above, once a chip comes into contact with the bonding surface 140, the step of alternating between receiving renewed position information of the substrate chuck and repositioning the bonding head (e.g., bonding head BH1, bonding head BH2, bonding head BH3) based on the received renewed position information ends. However, as best seen in FIGS. 16A and 16D, the remaining bonding head BH4 has been moved in the X dimension by the same distance 166 that the substrate moved. Thus, as shown in FIG. 4, at time t12, the bonding heads BH4 is still in the state represented by pattern 404 where the bonding head is moved to account for movement of the substrate. At the same time, in the illustrated example embodiment, as seen in FIG. 16B, the fourth bonding head BH4 has moved downwardly in the Z direction closer to the bonding surface. As illustrated in FIG. 16G the bonding head stage 120 tilts the chip chuck 120 of bonding head BH4 so that the fourth chip is aligned with the fourth target chip location 150d

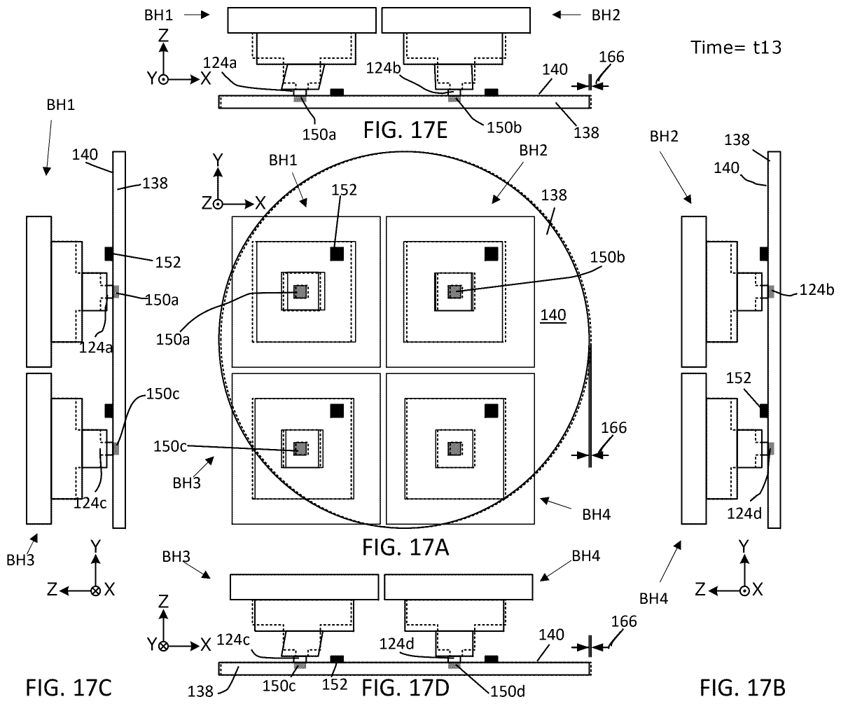

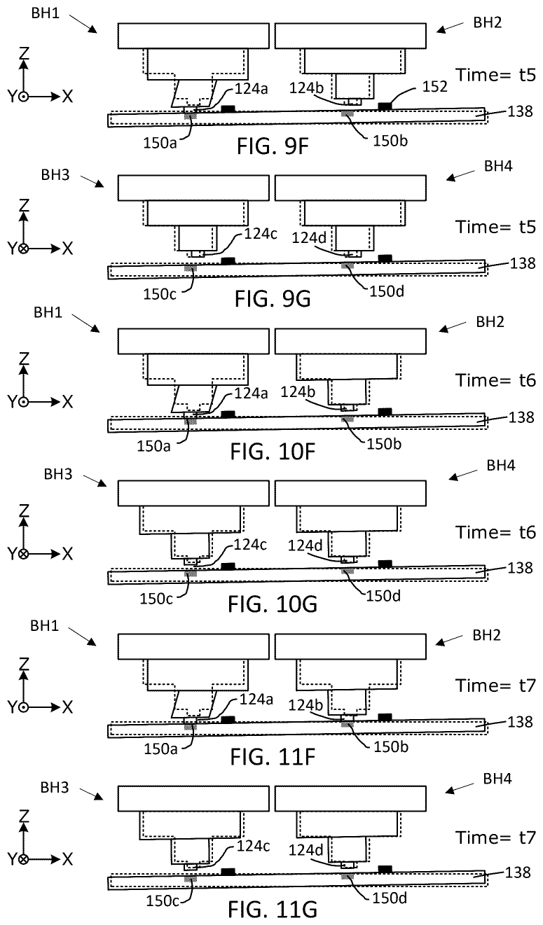

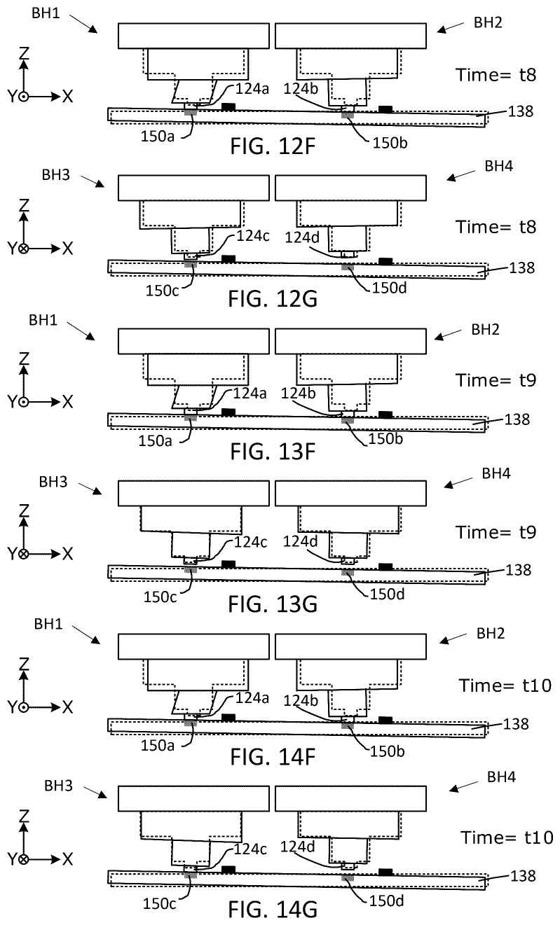

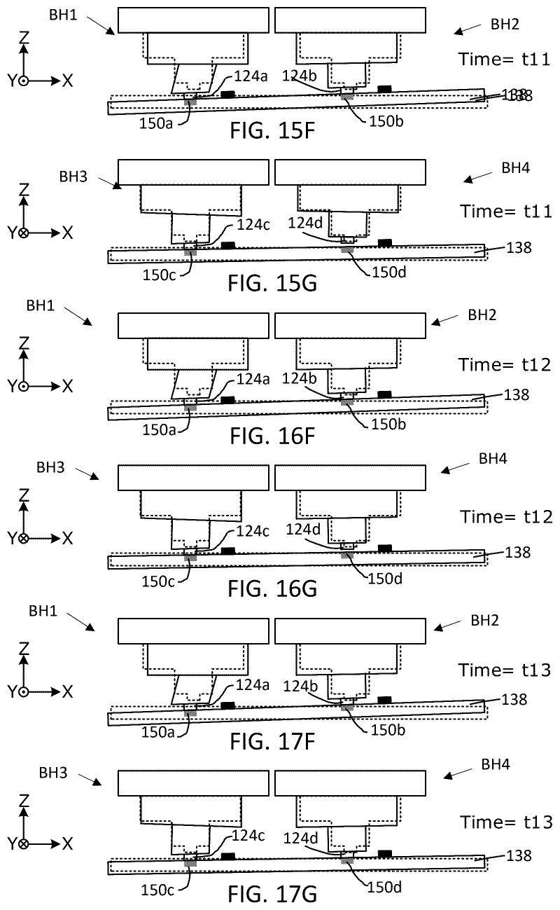

FIGS. 17A to 17G show different schematic views of the bonding heads and substrate positions at time t13 that occurs when the fourth chip 124d carried by the fourth bonding head BH4 comes into contact with the bonding surface 140, while all the other chips 124a, 124b, 124c remain in contact with bonding surface. FIG. 17A is a schematic top view of the bonding heads and substrate corresponding to the time t13 of FIG. 4. FIG. 17B is a schematic side view of the bonding heads and substrate in which the Y and Z dimensions are visible, at the same time t13. FIG. 17C is a schematic side view of the opposite side compared to FIG. 17B and also shows the bonding head and substrate such that the Y and Z dimensions are visible. FIG. 17D is a schematic side view of the bonding heads and substrate in which the X and Z dimensions are visible, at the same time t13. FIG. 17E is a schematic side view of the opposite side compared to FIG. 14D and also shows the bonding head and substrate such that the X and Z dimensions are visible. FIGS. 17F-G are schematic side views of the bonding heads and substrate in which the Y and Z dimensions are visible, at the same time t13 which shows the product substrate 138 tilted (θy) in a first direction and the fourth chip 124d brought into contact with the product substrate 138.

The timing chart of FIG. 4 shows when time t13 occurs. In the illustrated example embodiment, at the time t13, the chip 124d carried by the fourth bonding head BH4 has now come into contact with the bonding surface 140. The chip 124a carried by the first bonding head BH1, the chip 124b carried by the second bonding head BH2, and the chip 124c carried by the third bonding head BH3 previously came into contact with the bonding surface. As with the first chip 124a, the second chip 124b, and the third chip 124c, once the fourth chip 124d comes into contact with the bonding surface 140, the step of alternating between receiving renewed position information of the substrate chuck and repositioning the fourth bonding head based BH4 on the received renewed position information ends. That is, there is no longer any further adjustment of the position of the fourth bonding head BH4 whose chip has come into contact with the bonding surface. Thus, in the example embodiment, at the time t13, the position of the fourth bonding head BH4 will no longer be adjusted even when the substrate moves.

As noted, the time t13 shown in FIGS. 17A to 17E is the instant that the fourth, bonding head BH4 contacts the surface 140. Because the fourth bonding head BH4 is the final bonding head in the illustrated example embodiment, after the fourth chip 124d contacts the bonding surfacer 140, there is no longer any need to adjust the position of any of the bonding heads to compensate for a change in position of the substrate. Thus, in FIGS. 17A to 17E, as compared to time t12 shown in FIGS. 16A to 16E, there is no change in position of the bonding heads other than the fourth bonding head BH4 moving so that the fourth chip 124d comes into contact with the bonding surface 140. There is no X/Y movement of any bonding heads at this particular time t13 relative to time t12 because even if there is movement of the substrate, none of the bonding heads will move. As also shown in FIG. 4, once the fourth chip 124d carried by the fourth bonding head BH4 has contacted the bonding surface, the fourth bonding head BH4 enters a new state represented by the third pattern 406 of FIG. 4. That is, during the period of time represented by the third pattern 406 the fourth bonding head BH4 is no longer moved (i.e., no longer moved in X, Y, Z, tilt, tip, rotation) but the force imparted by the bonding head changes. As also shown in FIG. 4, just prior to the time t13, the state of the first bonding head BH1 and the second bonding head BH2 are still in the state represented by the fourth pattern 408, while the third bonding head BH3 has also entered into the state represented by the fourth pattern 408. As noted above, during the period of time represented by the fourth pattern 408, there is still no movement of the bonding head, but a constant low force is maintained in the Z direction. Thus, at the time t13 all of the first bonding head BH1, the second bonding head BH2, and the third bonding head BH3 are imparting a relatively low force to their respective chips that is a sufficient enough force to maintain an incomplete bond of the chip and the bonding surface, but not enough force to fully bond the entire surface area of the chip to the bonding surface.

FIG. 4 further shows a time t14, which is a time when the fourth bonding head BH4 has completed the state represented by the third pattern 406 and entered into the state represented by the fourth pattern 408 where there is still no movement of the bonding head, but a constant low force is maintained in the Z direction. Thus, at the time t14, all of the bonding heads are in the same state. That is, all of the chips are contacting the bonding surface, all of the bonding heads are stationary, and all of the bonding heads are imparting the relatively low force in the Z direction that that is a sufficient enough to maintain an incomplete bond of the chip and the bonding surface, but not enough force to fully bond the entire surface area of the chip to the bonding surface.

Notably, as also shown in FIG. 4, the time t15 is when all of the bonding heads switch from the state represented by the fourth pattern 408 to a new state represented by the fifth pattern 410. The fifth pattern in FIG. 4 represents a state where there is still no movement of the bonding heads, but a much higher bonding force is applied in the Z direction to the chips held by the bonding heads. The control state of each of the bonding head stages 120 while it is in the state represented by fifth pattern 410 is that each of the bonding head stages are in high constant force in the z direction and low to 0zero moment control without accounting for disturbances to the position of the product substrate on the product substrate chuck. The force applied during the state represented by the fifth pattern 410 is 2 to 20 times higher than force applied during the state presented by the fourth pattern 408. This force is sufficient to fully bond the chips to the bonding surface. Notably, the switch occurs at the same time t14 for all that bonding heads. That is, even though all of the other states may last for different times for different bonding heads, the timing is controlled so that all of the bonding heads switch from the state represented by the fourth pattern 408 to the state represented by the fifth pattern 410 at the same time. In other words, the relatively much stronger bonding force is applied to all of the chips at the same time. The bonding process ends at time tf when all of the chips have fully bonded to the bonding surface and the force applied by each of the bonding heads is no longer applied.

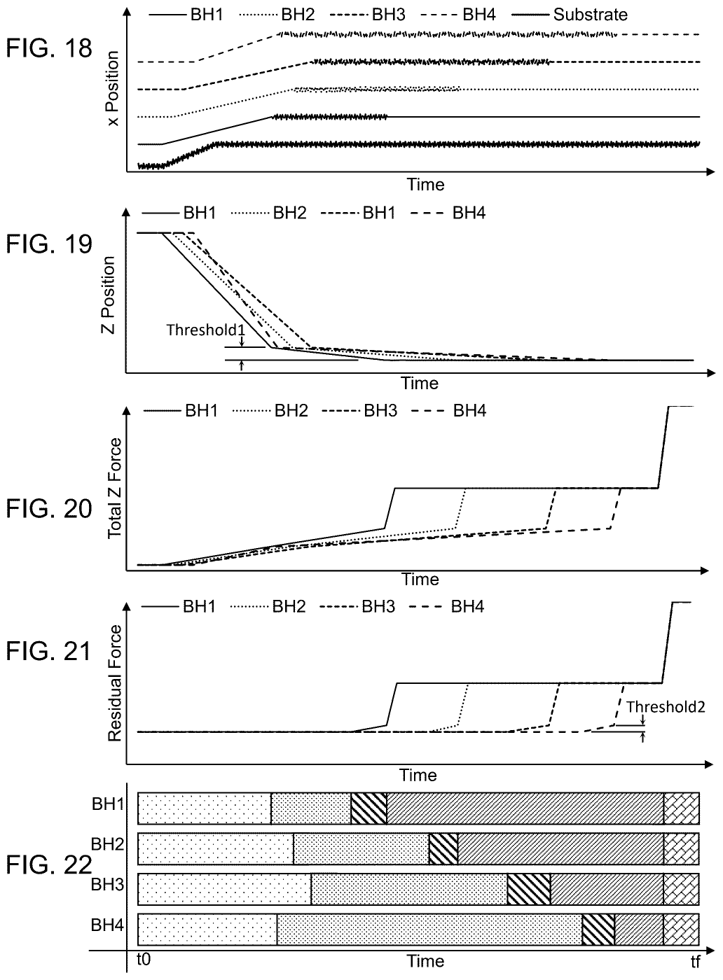

FIG. 18 shows a timing chart of the X dimension position control signals of the four bonding heads and the substrate measured position of the example embodiment. The X dimension position control signals are signals that the controller sends to bonding head stage 120. The x-axis represents the same time period of the timing chart of FIG. 4. The y-axis represents the X position. As seen in FIG. 18, in the example embodiment, from the start until the end of the bonding process, the substrate moves sporadically by relatively small amounts in the X direction. For each of the bonding heads and the substrate, FIG. 18 shows a ramp period where the substrate/bonding heads are moving to the overall predetermined initial X dimension position relative to a reference point. At the same time the bonding heads are moving toward the substrate in the Z direction.

FIG. 19 shows a timing chart of the Z dimension position of the four bonding heads. The x-axis represents the same time period of the timing chart of FIG. 4. The y-axis represents the Z position. As seen in FIG. 19, in the example embodiment, the bonding heads move toward the substrate at the same time as moving in the X direction (FIG. 18). Once a bonding head reaches a predetermined Z position threshold (Threshold1), the state of the bonding head switches from motion control without accounting for the position of the substrate to motion control with accounting for the position of the substrate. Threshold1 may be a Z-position that is small gap/distance from the product substrate. This gap may be 5 μm, 10 μm, 20 μm, 30 μm, 50 μm and 100 μm. The uniform lines in FIG. 18 becoming uneven indicates the adjustments being made to the X position control signals as a result of the movement of the substrate in the x direction. For each bonding head. when the processor detects the crossing of the Z position threshold (Threshold1) then the bonding head is operated in the control state represented by the second pattern 404.

FIG. 20 shows a timing chart of the total Z direction force imparted by the actuators of the four bonding heads (in Z direction) of the example embodiment. The x-axis represents the same time period of the timing chart of FIG. 4. The y-axis represents the total force (magnitude) applied by the actuators of the bonding head in the Z direction. The total force in the Z direction is the sum of all the Z direction force components of all of the actuators for a particular bonding head. That is, because each bonding head has multiple actuators to move in multiple directions, the Z component of each actuator is combined to arrive at the total Z force. As seen in FIG. 20, in the example embodiment, the total Z force steadily increases for each of the bonding heads until reaching a period where the total Z force is held constant. The period in which the total Z force is held constant the state represented by the fourth pattern 408 in FIG. 4. When the state is switched from the prior state (third pattern 406) to the fourth pattern 408 is determined when a second threshold (Threshold2) is reached.

Threshold2 is found in FIG. 21. FIG. 21 shows a timing chart of the residual force of the four bonding heads of the example embodiment. The x-axis represents the same time period of the timing chart of FIG. 4 starting. The y-axis represents the residual force. Because the bonding heads include flexures and springs that prevent all of the force of the actuators from being applied, the resulting actual force is the residual force. In other words, the residual Z force experienced by a chip is the total Z force applied by all the actuators of the bonding head carrying the chip balanced against the flexure/spring force. The excess Z force imparted by the actuators of the bonding head that overcomes the flexure/spring force is the residual force. The controller can calculate the residual force based on a measured position of the bonding head and subtracting the elastic forces of the bonding head stage 120 based on prior calibration data and measured positions of the bonding heads. When the predetermined residual Z force (Threshold2) is reached, then it is determined that contact has occurred, and the Z force applied to the chip that has made contact is quickly increased to a first magnitude of force that is insufficient to fully bond the chip to the bonding surface. The first magnitude is held constant once the chip makes contact and is applied to each subsequent chip as they make contact. Once all the chips have made contact and are held at the same total Z force and residual Z force, a second magnitude of force is simultaneously applied to all of the chips to fully bond the chips to the bonding surface. The magnitude of the second force is greater than a magnitude of the first force. The magnitude of the second force is 5-10 times greater than a magnitude of the first force.

FIG. 22 shows the same timing chart of FIG. 4. FIG. 22 is included alongside FIGS. 18-21 so that the states for the bonding heads are easily visible alongside the same times shown in FIGS. 18-21. That is, taken together, the charts in FIGS. 18-22 illustrate at any given time what the state of the bonding head is, what the X position is, what the Z position is, what the total Z force is, and what the residual Z force is.

While FIG. 18 is a chart of X position for the purposes of the example embodiment, the same principle may be applied to any of the other five dimensions, i.e., Y, Z, tilt, tip, rotation. FIGS. 18-22 are meant to be understood together, no scale has been given for any of the axis, the timing of the horizontal axis is the same for all of the figures and it is meant to show the correlated behavior of the different features of the bonding heads. The scale of the values is not meant to be quantitative but to give a qualitative understanding of the behavior of the bonding heads and the substrate.

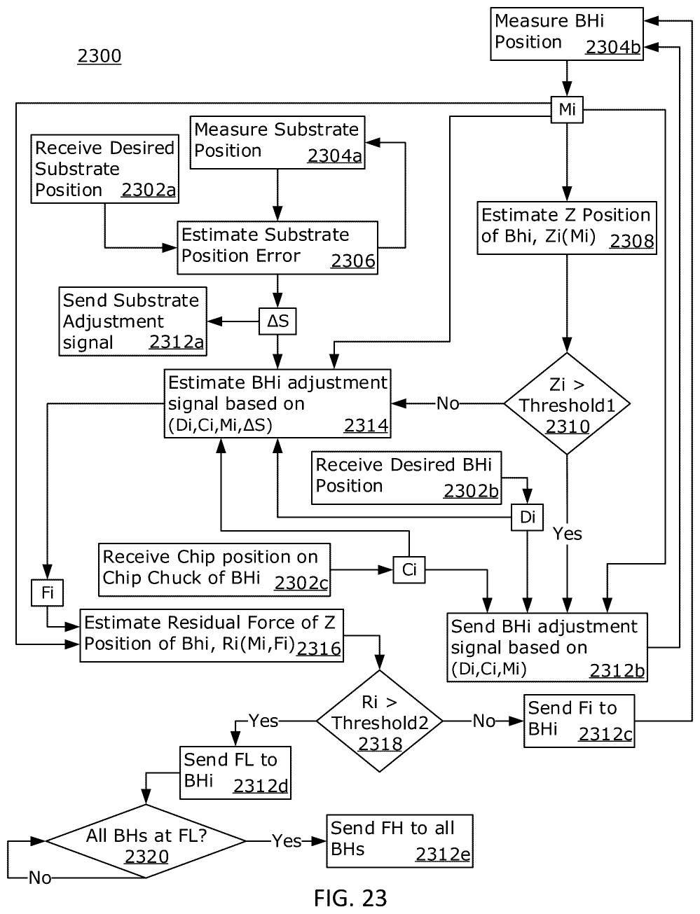

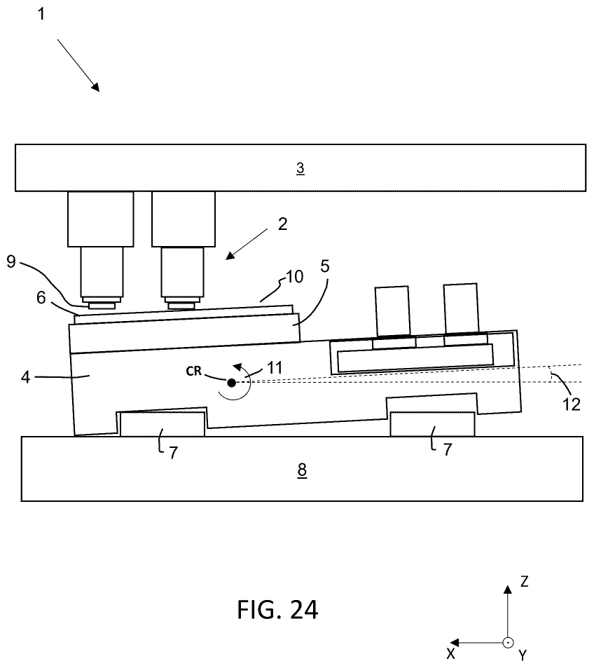

FIG. 23 is a flowchart showing a portion of the informational flow of a bonding process 2300 in the chip bonding section 106 of the bonding system 100. The bonding process 2300 include a first receiving step 2302a, a second receiving step 2304b and a third receiving step 2304c. The first receiving step 2302a includes processor 154 receiving the desired substrate position. The second receiving step 2302b includes processor 154 receiving the desired bonding head position Di of the i^{th} bonding head BHi of the N bonding heads. The third receiving step 2302b includes processor 154 receiving the measured chip position Ci of a chip 124 on the chip chuck 122 of the i^{th} bonding head BHi of the N bonding heads. The desired substrate position, the desired bonding head positions, and the chip positions may each include one to six coordinate positions.

The bonding process 2300 includes a substrate position measuring step 2304a and each bonding head BHi has a bonding head position measuring step 2304b. Each bonding head BHi may include one or more sensors for measuring the relative position of the chip chuck of each bonding head BHi in two to six coordinates which are then provided to the processor 154 as the measured bonding head position Mi for each chip chuck. The substrate position measuring step 2304a can include measuring the position of product substrate chuck.

The bonding process 2300 includes substrate position error estimation step 2306. During the substrate position error estimation step 2306, the processor 154 will estimate the position of the substrate based on the measured substrate position, calibration data, and known relative positions of the sensors, position and orientation of the substrate on the product substrate chuck, and target chip locations on the product substrate to determine the positions of a bonding surface of the product substrate. The processor 154 will then compare the estimated position of the substrate to the desired substrate position to find the substrate position error ΔS in one to six dimensions. The substrate position measuring step 2304a and the substrate position error estimation step 2306 are done repeatedly until the bonding process is finished. Typically the substrate position error ΔS will be large at first, but shrink over time, the substrate position error ΔS is captured continuously to take into account random and predictable disturbances. The substrate position error ΔS is then fed into a position controller such as proportional-integral-differential (PID) controller that determines what adjustment signal needs to be sent to the substrate positioning system. The bonding process 2300 includes a first sending step 2312a in which the processor sends the adjustment signal to the substrate positioning system.

The bonding process 2300 includes a Z position estimate step 2308. The Z position estimate step 2308 includes the processor estimating the position Zi which is the Z position of the chip chuck on the BHi based on the calibration data and the measured bonding head position Mi. The position Zi is compared to a threshold 1 in a first testing step 2310. If the Z position is greater than threshold1 then the bonding process 2300 moves to a second sending step 2312b, otherwise the bonding process 2300 moves to a first estimation step 2314. During the second sending step 2312b for each bonding head BHi, the processor 154 determines an adjustment signal to send to the bonding head stage to adjust the position of the chip chuck based on a PID controller, the chip position Ci, desired bonding head position Di, and the measured bonding head position Mi. The processor then sends the adjustment signal to the chip chuck of the bonding head BHi. Steps 2404b, 2308, 2310, and 2312b are done repeatedly until the answer to testing step 2310 is no.

When the answer to testing step 2310 is no, then the processor performs the estimation step 2314. The first estimation step 2314 includes determining for each bonding head BHi, an adjustment signal Fi to send to the bonding head stage to adjust the position of the chip chuck using a PID controller, the chip position Ci, desired bonding head position Di, the measured bonding head position Mi, and the substrate position error ΔS. After the first estimation step 2314 a second estimation step 2316 is performed by the processor. The second estimation step 2316 includes the processor estimating a residual force Ri for bonding head BHi based on an adjustment signal Fi, a measured bonding head position Mi, and calibration data.

The bonding process 2300 includes a processor performing the second testing step 2318. The second testing step 2318 includes the processor determining if the residual force Ri for bonding head BHi is greater than a Threshold2. If the answer to the second testing step 2318 is no, then the third sending step 2312c is performed otherwise a fourth sending step 2312d is performed. The third sending step 2312c includes the processor sending the adjustment signal Fi to the bonding head stage 120 of the BHi. If the answer to the first testing step 2310 is no then Steps 2304b, 2314, 2316, and 2318b are done repeatedly until the answer to the second testing step 2318 is yes.

When the answer to the second testing step 2318 is yes, then a fourth sending step 2312d is performed. The fourth sending step 2312d includes the processor sending instructions to the bonding head stage 120 of bonding head BHi to apply a low holding force FL while also maintaining low or zero Force Moment around the x and y axes (Mx and My). After the low holding force has been sent to the bonding head BHi, then the processor will continuously perform a third testing step 2320. The third testing step includes determining if all of the bonding heads have been held at the low hold force FL for more than a minimum low force holding time. If the answer to the third testing step 2320 is no, then the third testing step 2320 is repeatedly performed on a regular basis. If the answer to the third testing step 2320 is yes, then a fourth sending step 2312e is performed. The fourth sending step 2322 includes sending instructions to the bonding head stage 120 apply a high holding force with low or zero force moments around the x and y axis (Mx and My). After the fourth sending step has been performed for a high force holding time, then all of the chips are released from the chip chuck and all the bonding heads are moved away from the product substrate chuck with the bonding head stages.

After all of the chips have been fully bonded to bonding surface, all of the bonded chips are released from the bonding head. That is, with the chips being bonded on one side of the chip to the bonding surface, the bonding heads may release the opposite side of the chip being held by the bonding heads. Once released, the bonding process has been completed. At this point, the bonding process can be repeated using more chips.

By implementing the bonding method described herein, alignment error due to tilt or alignment error due to any other disturbances to the substrate, is eliminated or minimized. In particular, because the position of each of the bonding heads is adjusted based on the position of the substrate (substrate chuck) until the chip carried by the bonding head contacts the bonding surface, the impact of the movement of the substrate on alignment is eliminated or minimized. That is, any movement of the substrate while the chip is approaching the bonding surface is accounted for by moving the bonding head carrying the chip.

After process of bonding chips to bonding surface is complete (which may include many cycles of the bonding method 200 to bond hundreds, thousands, or tens of thousands of chips), the product substrate 138 is removed from the chip bonding section 106 by for example the transfer robot 126 or the like. The product substrate may then be subjected to an annealing process (which may include one or both of heat and pressure) in which the hybrid bonding process is completed. The product substrate may be subjected to additional processes in which additional chips are added to the product substrate before or after the annealing process. The product substrate may then be subjected to additional processes, such as: singulation, testing, encapsulation, etc., which are used to produce a plurality of articles from the product substrate.

Note that not all of the activities described above in the general description or the examples are required, that a portion of a specific activity may not be required and that one or more further activities can be performed in addition to those described. Still further, the order in which activities are listed is not necessarily the order in which they are performed. While the above description, was described in the context of hybrid bonding process, other bonding processes may be used such as soldering, flip-chip bonding, ball grid array bonding, or another process that used to form a plurality of electrical connections between chips.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A method for bonding chips, comprising:
initially positioning a first bonding head at a first predetermined location relative to an initial position of a substrate chuck, wherein the first bonding head holds a first chip and wherein the substrate chuck supports a bonding surface;
initially positioning a second bonding head at a second predetermined location relative to the initial position of the substrate chuck, wherein the second bonding head holds a second chip;
alternating between receiving renewed position information of the substrate chuck and repositioning the first bonding head based on the received renewed position information until the first chip contacts the bonding surface; and
alternating between receiving renewed position information of the substrate chuck and repositioning the second bonding head based on the received renewed position information until the second chip contacts the bonding surface; and
bonding the first chip and the second chip to the bonding surface.

2. The method of claim 1,
wherein the alternating between receiving the renewed position information and the repositioning of the first bonding head until the first chip contacts the bonding surface occurs for a first time period,
wherein the alternating between receiving the renewed position information and the repositioning the second bonding head until the second chip contacts the bonding surface occurs for a second time period, and
wherein the first time period and the second time period overlap.

3. The method of claim 1,
wherein a duration of the first time period is different than a duration of the second time period.

4. The method of claim 1, further comprising:
after the first chip contacts the bonding surface, actuating the bonding head to impart a first force on the first chip in a direction toward the bonding surface; and
after the second chip contacts the bonding surface, actuating the second bonding head to impart a second force on the second chip in a direction toward the bonding surface.

5. The method of claim 4, further comprising:
after imparting the first force and the second force, simultaneously actuating the first bonding and the second bonding head such that the first bonding head imparts a third force on the first chip in the direction toward the bonding surface and the second bonding head imparts a fourth force on the second chip in the direction toward the bonding surface.

6. The method of claim 5,
wherein a magnitude of the third force is sufficient to fully bond the first chip to the bonding surface, and
wherein a magnitude of the fourth force is sufficient to fully bond the second chip to the bonding surface.

7. The method of claim 5,
wherein a magnitude of the third force is greater than a magnitude of the first force, and
wherein a magnitude of the fourth force is greater than a magnitude of the second force.

8. The method of claim 5,
wherein a magnitude of the first force is 10%+/−a magnitude of the second force, and
wherein a magnitude of the third force is 10%+/−a magnitude of the fourth force.

9. The method of claim 5,
wherein a magnitude of the third force is 10 times greater than a magnitude of the first force, and
wherein a magnitude of the fourth force is 10 times greater than a magnitude of the second force.

10. The method of claim 4,
wherein a magnitude of the first force is insufficient to fully bond the first chip to the bonding surface,
wherein a magnitude of the second force is insufficient to fully bond the second chip to the bonding surface.

11. The method of claim 1, further comprising:
initially positioning a third bonding head at a third predetermined location relative to the initial position of a substrate chuck, wherein the third bonding head holds a third chip; and
alternating between receiving renewed position information of the substrate chuck and repositioning the third bonding head based on the received renewed position information until the third chip contacts the bonding surface.

12. The method of claim 11,
wherein the alternating between receiving the renewed position information and the repositioning of the first bonding head until the first chip contacts the bonding surface occurs for a first time period,
wherein the alternating between receiving the renewed position information and the repositioning the second bonding head until the second chip contacts the bonding surface occurs for a second time period,
wherein the alternating between receiving the renewed position information and the repositioning the third bonding head until the third chip contacts the bonding surface occurs for a third time period, and
wherein the first time period, the second time period, and the third time period overlap.

13. The method of claim 11, further comprising:
after the first chip contacts the bonding surface, actuating the bonding head to impart a first force on the first chip in a direction toward the bonding surface;
after the second chip contacts the bonding surface, actuating the second bonding head to impart a second force on the second chip in a direction toward the bonding surface; and
after the third chip contacts the bonding surface, actuating the third bonding head to impart a third force on the second chip in a direction toward the bonding surface.

14. The method of claim 13, further comprising:
after imparting the first force, the second force, and the third force, simultaneously actuating the first bonding, the second bonding head, and the third bonding head such that the first bonding head imparts a fourth force on the first chip in the direction toward the bonding surface, the second bonding head imparts a fifth force on the second chip in the direction toward the bonding surface, and the third bonding head imparts a sixth force on the third chip in the direction toward the bonding surface.

15. The method of claim 14,
wherein a magnitude of the first force, a magnitude of the second force, and a magnitude of the third force are each insufficient to fully bond the first chip, the second chip, and the third chip to the bonding surface, and
wherein a magnitude of the fourth force, a magnitude of the fifth force, and a magnitude of the sixth force are each sufficient to fully bond the first chip, the second chip, and the third chip to the bonding surface.

16. The method of claim 1, further comprising:
upon the first chip contacting the bonding surface, terminating the repositioning of the first bonding head; and
upon the second chip contacting the bonding surface, terminating the repositioning of the second bonding head.

17. The method of claim 16, the further comprising:
after the first chip contacts bonding surface and before the second chip contacts the bonding surface, continuing to alternate between receiving renewed position information of the substrate chuck and repositioning the second bonding head based on the received renewed position information.

18. The method of claim 1,
wherein the renewed position information includes one or more of renewed X position information, renewed Y position information, renewed tilt information, renewed rotation information, and renewed tip information.

19. A system for bonding chips, comprising:
a first bonding head configured to hold a first chip;
a second bonding head configured to hold a second chip;
a substrate chuck supporting a bonding surface;
one or more processors; and
one or more memories storing instructions, when executed by the one or more processors, causing the system to:
initially position the first bonding head at a first predetermined location relative to an initial position of a substrate chuck;
initially position a second bonding head at a second predetermined location relative to the initial position of the substrate chuck;
alternate between receiving renewed position information of the substrate chuck and repositioning the first bonding head based on the received renewed position information until the first chip contacts the bonding surface;
alternate between receiving renewed position information of the substrate chuck and repositioning the second bonding head based on the received renewed position information until the second chip contacts the bonding surface; and
bond the first chip and the second chip to the bonding surface.

20. A method of manufacturing a plurality of articles, comprising:
initially positioning a first bonding head at a first predetermined location relative to an initial position of a substrate chuck, wherein the first bonding head holds a first chip and wherein the substrate chuck supports a substrate;
initially positioning a second bonding head at a second predetermined location relative to the initial position of the substrate chuck, wherein the second bonding head holds a second chip;
alternating between receiving renewed position information of the substrate chuck and repositioning the first bonding head based on the received renewed position information until the first chip contacts the substrate;
alternating between receiving renewed position information of the substrate chuck and repositioning the second bonding head based on the received renewed position information until the second chip contacts the substrate;
bonding the first chip and the second chip to the substrate;
singulating the substrate to produce the plurality of articles.
